(19) United States
(12) Patent Application Publication
(10) Pub. No.: US 2026/0026161 A1
(43) Pub. Date: Jan. 22, 2026

(54) DISPLAY DEVICE

(71) Applicants: LG ELECTRONICS INC., Seoul (KR); LG DISPLAY CO., LTD., Seoul (KR)

(72) Inventors: Jaewon CHANG, Seoul (KR); Wonseok CHOI, Seoul (KR)

(73) Assignees: LG ELECTRONICS INC., Seoul (KR); LG DISPLAY CO., LTD., Seoul (KR)

(21) Appl. No.: 18/995,564

(22) PCT Filed: Jul. 26, 2022
(86) PCT No.: PCT/KR2022/010958

§ 371 Date: Jan. 16, 2025

(51) Int. Cl. H10H 29/49; H10H 20/832; H10H 20/833

(52) U.S. Cl. CPC H10H 29/49; H10H 20/833; H10H 20/835

(57) ABSTRACT

The display device may include a substrate, a first assembly wiring on the substrate, a second assembly wiring on the substrate, a partition wall including an assembly hole on the first assembly wiring and the second assembly wiring, a semiconductor light-emitting element in the assembly hole, a connection electrode on a side portion of the semiconductor light-emitting element, and an electrode wiring on an upper side of the semiconductor light-emitting element. Each of the first assembly wiring and the second assembly wiring may include a first conductive electrode vertically overlapping the assembly hole, and a second conductive electrode connected to the first conductive electrode and vertically overlapping the semiconductor light-emitting element.

### TECHNICAL FIELD

The embodiment relates to a display device.

### BACKGROUND ART

A large-area display includes a liquid crystal display (LCD), an OLED display, and a micro-LED display.

The micro-LED display is a display that uses micro-LEDs, which are semiconductor light-emitting elements with a diameter or cross-sectional area of 100 μm or less, as display elements.

Since the micro-LED display uses micro-LEDs, which are semiconductor light-emitting elements, as display elements, it has excellent performance in many characteristics such as contrast ratio, response speed, color reproducibility, viewing angle, brightness, resolution, lifespan, luminescence efficiency, and luminance.

In particular, the micro-LED display has the advantage of being able to freely adjust the size or resolution and implement a flexible display because the screen can be separated and combined in a modular manner.

However, since a large-area micro-LED display requires millions or more micro-LEDs, there is a technical problem that it is difficult to quickly and accurately transfer micro-LEDs to a display panel.

Recently developed transfer technologies include the pick and place process, the laser lift-off method, and the self-assembly method.

Among these, the self-assembly method is a method in which semiconductor light-emitting elements find their assembly positions in a fluid on their own, which is advantageous for implementing a large-screen display device.

However, research on the technology for manufacturing display through self-assembly of micro-LEDs is still insufficient.

In particular, in the conventional technology, when transferring millions or more semiconductor light-emitting elements to a large display quickly, the transfer speed can be improved, but the transfer error rate can increase, which causes a technical problem in that the transfer yield is low.

In the related technology, a self-assembly transfer process using dielectrophoresis (DEP) is being attempted, but there is a problem in that the self-assembly rate is low due to the unevenness of the DEP force.

Meanwhile, according to the non-public internal technology, after the semiconductor light-emitting element is assembled on a substrate by the self-assembly method, a post-process for electrical connection to the semiconductor light-emitting element is performed.

FIG. 1A and FIG. 1B illustrate a display device according to the non-public internal technology.

As illustrated in FIG. 1A and FIG. 1B, after a semiconductor light-emitting element 3 is assembled in an assembly hole 1H of a partition wall 1, a connection electrode 4 may be formed on a side portion of the semiconductor light-emitting element 3. Then, an insulating layer 5 may be formed on the partition wall 1, and an electrode wiring 6 is connected to an upper side of the semiconductor light-emitting element 3 through a contact hole 2.

The contact hole 2 may be formed on the semiconductor light-emitting element 3 using an exposure process. To this end, as illustrated in FIG. 2A and FIG. 2B, a pattern mask 7 comprising a pattern hole 8 is positioned on the insulating layer 5. Thereafter, an alignment process is performed so that the pattern hole 8 is positioned at a center of the semiconductor light-emitting element 3.

However, when the pattern hole 8 of the pattern mask 7 is shifted due to misalignment and the exposure process is performed, the contact hole 2 may be formed so that the connection electrode 4 is exposed. Then, as illustrated in FIG. 3, when the electrode wiring 6 is formed in the contact hole 2, the electrode wiring 6 is electrically shorted with the connection electrode 4. In this instance, the semiconductor light-emitting element 3 does not emit light, resulting in a problem of poor emission.

Meanwhile, depending on the position of the focus of the beam spot during exposure, contact holes 2 having various sizes are generated. As illustrated in FIG. 4(a), when the exposure process is performed after the beam spot is positioned on the upper side of the semiconductor light-emitting element 3, a normal contact hole 2 is formed. However, as illustrated in FIG. 4(b), when the beam spot is positioned on the upper side of the semiconductor light-emitting element 3, the size of the contact hole 2 is very small and is processed abnormally. As illustrated in FIG. 4(c), when the beam spot is positioned on an inner side of the semiconductor light-emitting element 3, the size of the contact hole 2 is very large and is processed abnormally. In particular, as illustrated in FIG. 4(c), when the size of the contact hole 2 is greater than the size of the semiconductor light-emitting element 3, not only the upper surface of the semiconductor light-emitting element 3 but also the connection electrode 4 is exposed, so that there is a problem that an electrical short occurs between the electrode wiring 6 and the connection electrode 4 as described above.

### DISCLOSURE

### Technical Problem

An object of the embodiment is to solve the foregoing and other problems.

Another object of the embodiment is to provide a display device.

In addition, another object of the embodiment is to provide a display device capable of preventing an electrical short defect.

In addition, another object of the embodiment is to provide a display device having a simple structure.

In addition, another object of the embodiment is to provide a display device capable of improving luminance.

In addition, another object of the embodiment is to provide a display device having an easy process.

In addition, another object of the embodiment is to provide a display device capable of strengthening fixing force.

The technical problems of the embodiments are not limited to those described in this item and include those that can be understood through the description of the invention.

### Technical Solution

In order to achieve the above or other objects, according to one aspect of the embodiment, a display device, comprising: a substrate: a first assembling wiring on the substrate: a second assembling wiring on the substrate: a partition wall comprising an assembly hole on the first assembling wiring and the second assembling wiring: a semiconductor light-emitting element in the assembly hole: a connection electrode on a side portion of the semiconductor light-emitting element: and an electrode wiring on an upper side of the semiconductor light-emitting element, wherein each of the first assembling wiring and the second assembling wiring comprises: a first conductive electrode configured to vertically overlap the assembly hole: and a second conductive electrode configured to be connected to the first conductive electrode and vertically overlap the semiconductor light-emitting element.

The substrate may comprise a first subpixel, a second subpixel, and a third subpixel, the semiconductor light-emitting element may comprise at least one first semiconductor light-emitting element in the first subpixel: at least one second semiconductor light-emitting element in the second subpixel: and at least one third semiconductor light-emitting element in the third subpixel, and each of the first semiconductor light-emitting element, the second semiconductor light-emitting element, and the third semiconductor light-emitting element may emit different light.

The electrode wiring may be commonly connected to the first semiconductor light-emitting element, the second semiconductor light-emitting element, and the third semiconductor light-emitting element.

The connection electrode may comprise a first connection electrode around the first semiconductor light-emitting element of the first subpixel: a second connection electrode around the second semiconductor light-emitting element of the second subpixel: and a third connection electrode around the third semiconductor light-emitting element of the third subpixel.

Each of the first semiconductor light-emitting element, the second semiconductor light-emitting element, and the third semiconductor light-emitting element may comprise a light-emitting layer; and a side electrode configured to extend from a lower side of the light-emitting layer and disposed on a side portion of the light-emitting layer, and each of the first connection electrode, the second connection electrode, and the third connection electrode may be in contact with the side electrode.

Each of the first connection electrode, the second connection electrode, and the third connection electrode may be connected to at least one of the first assembling wiring or the second assembling wiring.

Each of the first connection electrode, the second connection electrode, and the third connection electrode may be in contact with the first conductive electrode.

Each of the first connection electrode, the second connection electrode, and the third connection electrode may be in contact with the second conductive electrode.

The electrode wiring may be disposed on the first semiconductor light-emitting element, the second semiconductor light-emitting element, the third semiconductor light-emitting element, and the partition wall.

The electrode wiring may be disposed on an upper surface of each of the first semiconductor light-emitting element, the second semiconductor light-emitting element, and the third semiconductor light-emitting element.

The upper surface of each of the first semiconductor light-emitting element, the second semiconductor light-emitting element, and the third semiconductor light-emitting element may be positioned on a same horizontal line as an upper surface of the partition wall.

At least one of the first assembling wiring or the second assembling wiring may be an anode electrode, and the electrode wiring may be a cathode electrode.

The first conductive electrode may be a metal electrode.

The second conductive electrode may be a transparent electrode, and the electrode wiring may be a reflective electrode.

The second conductive electrode may be a reflective electrode, and the electrode wiring may be a transparent electrode.

The semiconductor light-emitting element may have an inclined surface so that a size of the lower side thereof may be greater than a size of an upper side thereof.

### Advantageous Effects

As illustrated in FIGS. 1A and 1B, when the insulating layer 5 is formed on the semiconductor light-emitting element 3, the contact hole 2 may be formed in the insulating layer 5 corresponding to the upper side of the semiconductor light-emitting element 3 for electrical connection of the upper side of the semiconductor light-emitting element 3. However, as illustrated in FIGS. 2A and 2B, when the exposure process is performed in a state where the pattern mask 7 is misaligned, the contact hole 2 may be formed where the connection electrode 4 is exposed outside the center of the semiconductor light-emitting element 3. In this instance, as illustrated in FIG. 3, the electrode wiring 6 and the connection electrode 4 are electrically short-circuited, resulting in a lighting defect in which the semiconductor light-emitting element 3 does not emit light.

According to an embodiment, as illustrated in FIGS. 11 to 13, an electrode wiring 360 may be directly connected to an upper side of each of a first semiconductor light-emitting element 150-1, a second semiconductor light-emitting element 150-2, and a third semiconductor light-emitting element 150-3 without penetrating a separate insulating layer. That is, a separate insulating layer is not formed on the first semiconductor light-emitting element 150-1, the second semiconductor light-emitting element 150-2, and the third semiconductor light-emitting element 150-3. For example, an upper surface of the second insulating layer 350 formed in each of a first assembly hole 340H1, a second assembly hole 340H2, and a third assembly hole 340H3 may be positioned on the same horizontal line as an upper surface of each of the first semiconductor light-emitting element 150-1, the second semiconductor light-emitting element 150-2, and the third semiconductor light-emitting element 150-3, so that the second insulating layer 350 is not formed on the first semiconductor light-emitting element 150-1, the second semiconductor light-emitting element 150-2, and the third semiconductor light-emitting element 150-3.

In this instance, since the electrode wiring 360 is disposed on the first semiconductor light-emitting element 150-1, the second semiconductor light-emitting element 150-2, and the third semiconductor light-emitting element 150-3, the electrode wiring 360 may be directly in contact with the upper surfaces of the first semiconductor light-emitting element 150-1, the second semiconductor light-emitting element 150-2, and the third semiconductor light-emitting element 150-3 without the interference of a separate insulating layer. Therefore, as illustrated in FIGS. 2A to 3, when the contact hole 2 is incorrectly positioned, not in the correct position, due to misalignment of the pattern mask 7 in the insulating layer 5 formed on the semiconductor light-emitting element 3, an electrical short may occur between the electrode wiring 6 and the connection electrode 4 through the contact hole 2. However, the electrical short problem may be solved by the structure of the embodiment.

Meanwhile, as illustrated in FIGS. 11 to 13 and FIG. 25, the electrode wiring 360 is integrally formed on the display region DA of the display panel 10, and the electrode wiring 360 may be used as a cathode electrode. For example, a fixed voltage, for example a reference voltage of 0 V, may be supplied to the electrode wiring 360. Therefore, there is no need to separate and insulate the electrode wiring 360 connected to the upper side of each of the first semiconductor light-emitting element 150-1, the second semiconductor light-emitting element 150-2, and the third semiconductor light-emitting element 150-3. Accordingly, since the electrode wiring 360 is formed by depositing a conductive film on the display region DA of the display panel 10, the structure is simple and the process is easy.

Meanwhile, as illustrated in FIGS. 15 and 16, a part of the light generated from the first semiconductor light-emitting element 150-1 (the same applies to the second semiconductor light-emitting element 150-2 and the third semiconductor light-emitting element 150-3) is reflected to contribute to light output in a specific direction, i.e., the forward direction or the backward direction, thereby improving luminance.

Additional scope of applicability of the embodiments will become apparent from the detailed description that follows. However, since various changes and modifications within the idea and scope of the embodiments may be clearly understood by those skilled in the art, the detailed description and specific embodiments, such as preferred embodiments, should be understood as being given by way of example only.

### DESCRIPTION OF DRAWINGS

FIGS. 1A and 1B illustrate a display device according to a non-public internal technology.

FIGS. 2A and 2B illustrate a state in which a contact hole is formed so that a connection electrode is exposed by misalignment.

FIG. 3 illustrates an appearance in which an electrode wiring is electrically shorted with a connection electrode through a contact hole.

FIG. 4 illustrates various contact holes formed by a contact hole forming process.

FIG. 5 illustrates a living room of a house in which a display device according to an embodiment is disposed.

FIG. 6 is a block diagram schematically showing a display device according to an embodiment.

FIG. 7 is a circuit diagram showing an example of a pixel of FIG. 6.

FIG. 8 is an enlarged view of a first panel region in the display device of FIG. 5.

FIG. 9 is an enlarged view of a region A2 of FIG. 8.

FIG. 10 is a drawing illustrating an example in which a light-emitting element according to an embodiment is assembled on a substrate by a self-assembly method.

FIG. 11 is a plan view illustrating a display device according to an embodiment.

FIG. 12 is a plan view illustrating a display device according to an embodiment in more detail.

FIG. 13 is a cross-sectional view taken along the C1-C2 line in the display device according to the embodiment of FIG. 12.

FIG. 14 is a cross-sectional view illustrating the first semiconductor light-emitting element of the embodiment.

FIG. 15 illustrates an image displayed according to the bottom emission method in the display device according to the embodiment.

FIG. 16 illustrates an image displayed according to the top emission method in the display device according to the embodiment.

FIGS. 17 to 24 are cross-sectional views illustrating a manufacturing process of the display device according to the embodiment.

FIG. 25 is a block diagram illustrating a display device according to the embodiment.

The sizes, shapes, dimensions, etc. of elements illustrated in the drawings can differ from actual ones. In addition, even if the same elements are illustrated in different sizes, shapes, dimensions, etc. between the drawings, this is only an example on the drawing, and the same elements have the same sizes, shapes, dimensions, etc. between the drawings.

### MODE FOR INVENTION

Hereinafter, the embodiment disclosed in this specification will be described in detail with reference to the accompanying drawings, but the same or similar elements are given the same reference numerals regardless of reference numerals, and redundant descriptions thereof will be omitted. The suffixes ‘module’ and ‘unit’ for the elements used in the following descriptions are given or used interchangeably in consideration of ease of writing the specification, and do not themselves have a meaning or role that is distinct from each other. In addition, the accompanying drawings are for easy understanding of the embodiment disclosed in this specification, and the technical idea disclosed in this specification is not limited by the accompanying drawings. Also, when an element such as a layer, region or substrate is referred to as being ‘on’ another element, this means that there can be directly on the other element or be other intermediate elements therebetween.

The display devices described in this specification may comprise a TV, a signage, a mobile phone, a smart phone, a head-up display (HUD) for automobile, a backlight unit for a laptop computer, a display for VR or AR, etc. However, the configuration according to the embodiment described in this specification may be applied to a new product type developed in the future, as well as a device capable of display.

Hereinafter, a light-emitting element according to an embodiment and a display device comprising the same will be described.

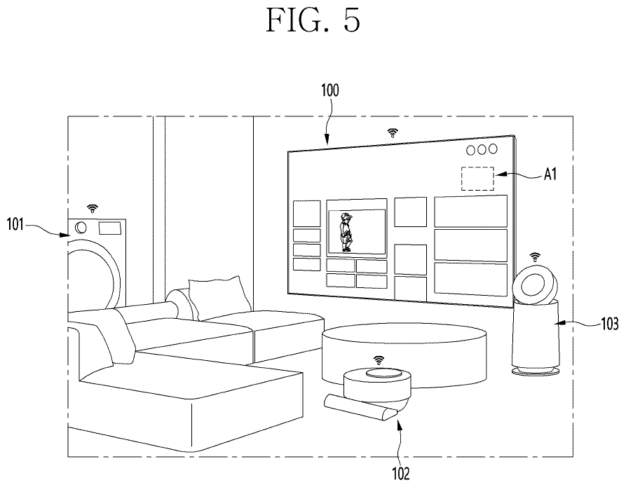

FIG. 5 illustrates a living room of a house in which a display device according to an embodiment is disposed.

Referring to FIG. 5, the display device 100 according to the embodiment may display the status of various electronic products such as a washing machine 101, a robot vacuum cleaner 102, an air purifier 103, etc., and may communicate with each electronic product based on IOT, and may also control each electronic product based on user setting data.

The display device 100 according to the embodiment may comprise a flexible display manufactured on a thin and flexible substrate. The flexible display may be bent or rolled like paper while maintaining the characteristics of an existing flat display.

In the flexible display, visual information may be implemented by independently controlling the light emission of unit pixels disposed in a matrix form. A unit pixel means a minimum unit for implementing one color. A unit pixel of a flexible display may be implemented by a light-emitting element. In an embodiment, the light-emitting element may be a micro-LED or a nano-LED, but is not limited thereto.

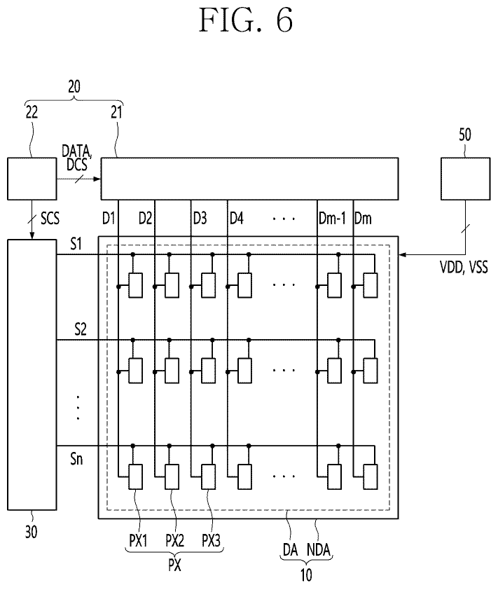

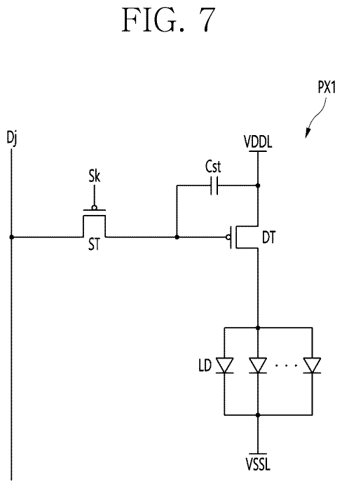

FIG. 6 is a block diagram schematically showing a display device according to an embodiment, and FIG. 7 is a circuit diagram showing an example of a pixel of FIG. 6.

Referring to FIGS. 6 and 7, the display device according to an embodiment may comprise a display panel 10, a driving circuit 20, a scan driving unit 30, and a power supply circuit 50.

The display device 100 of the embodiment may drive a light-emitting element in an active matrix (AM) manner or a passive matrix (PM) manner.

The driving circuit 20 may comprise a data driving unit 21 and a timing control unit 22.

The display panel 10 may be formed in a rectangular shape, but is not limited thereto. That is, the display panel 10 may be formed in a circular shape or oval shape. At least one side of the display panel 10 may be formed to be bent at a predetermined curvature.

The display panel 10 may be divided into a display region DA and a non-display region NDA disposed around the display region DA. The display region DA is a region where pixels PX are formed and display an image. The display panel 10 may comprise data lines (D1 to Dm, m is an integer greater than or equal to 2), scan lines (S1 to Sn, n is an integer greater than or equal to 2) crossing the data lines D1 to Dm, a high-potential voltage line VDDL supplied with a high-potential voltage, a low-potential voltage line VSSL supplied with a low-potential voltage VSS, and pixels PX connected to the data lines D1 to Dm and the scan lines S1 to Sn.

Each of the pixels PX may comprise a first subpixel PX1, a second subpixel PX2, and a third subpixel PX3. The first subpixel PXI may emit a first color light of a first dominant wavelength, the second subpixel PX2 may emit a second color light of a second dominant wavelength, and the third subpixel PX3 may emit a third color light of a third dominant wavelength. The first color light may be red light, the second color light may be green light, and the third color light may be blue light, but is not limited thereto. In addition, although FIG. 6 illustrates that each of the pixels PX comprises three subpixels, the present invention is not limited thereto. That is, each of the pixels PX may comprise four or more subpixels.

Each of the first subpixel PX1, the second subpixel PX2, and the third subpixel PX3 may be connected to at least one of the data lines D1 to Dm, at least one of the scan lines S1 to Sn, and a high-potential voltage line VDDL. The first subpixel PX1 may comprise light-emitting elements LD, a plurality of transistors for supplying current to the light-emitting elements LD, and at least one capacitor Cst, as illustrated in FIG. 7.

Although not illustrated in the drawing, each of the first subpixel PX1, the second subpixel PX2, and the third subpixel PX3 may comprise only one light-emitting element LD and at least one capacitor Cst.

Each of the light-emitting elements LD may be a semiconductor light-emitting diode comprising a first electrode, a plurality of conductivity type semiconductor layers, and a second electrode. Here, the first electrode may be an anode electrode, and the second electrode may be a cathode electrode, but is not limited thereto.

The light-emitting element LD may be one of a lateral-type light-emitting element, a flip-chip type light-emitting element, and a vertical-type light-emitting element.

The plurality of transistors may comprise a driving transistor DT for supplying current to the light-emitting elements LD, and a scan transistor ST for supplying a data voltage to a gate electrode of the driving transistor DT, as illustrated in FIG. 7. The driving transistor DT may comprise a gate electrode connected to a source electrode of the scan transistor ST, a source electrode connected to a high-potential voltage line VDDL to which a high-potential voltage is applied, and a drain electrode connected to the first electrodes of the light-emitting elements LD. The scan transistor ST may comprise a gate electrode connected to a scan line (Sk, where k is an integer satisfying 1≤k≤n), a source electrode connected to the gate electrode of the driving transistor DT, and a drain electrode connected to a data line (Dj, where j is an integer satisfying 1≤j≤m).

The capacitor Cst may be formed between the gate electrode and the source electrode of the driving transistor DT. The storage capacitor Cst charges the difference between a gate voltage and a source voltage of the driving transistor DT.

The driving transistor DT and the scan transistor ST may be formed as thin film transistors. In addition, in FIG. 7, the driving transistor DT and the scan transistor ST are described mainly as being formed as P-type metal oxide semiconductor field effect transistors (MOSFETs), but the present invention is not limited thereto. The driving transistor DT and the scan transistor ST may also be formed as N-type MOSFETs. In this instance, the positions of the source electrodes and the drain electrodes of each of the driving transistor DT and the scan transistor STs may be changed.

In addition, in FIG. 7, the first subpixel PX1, the second subpixel PX2, and the third subpixel PX3 are exemplified as comprising 2T1C (2 Transistor—1 capacitor) having one driving transistor DT, one scan transistor ST, and one capacitor Cst, but the present invention is not limited thereto. Each of the first subpixel PX1, the second subpixel PX2, and the third subpixel PX3 may comprise a plurality of scan transistors ST and a plurality of capacitors Cst.

Since the second subpixel PX2 and the third subpixel PX3 may be expressed by substantially the same circuit diagram as the first subpixel PX1, a detailed description thereof will be omitted.

The driving circuit 20 outputs signals and voltages for driving the display panel 10. To this end, the driving circuit 20 may comprise a data driving unit 21 and a timing control unit 22.

The data driving unit 21 receives digital video data DATA and a source control signal DCS from the timing control unit 22. The data driving unit 21 converts digital video data DATA into analog data voltages according to the source control signal DCS and supplies the converted data to data lines DI to Dm of the display panel 10.

The timing control unit 22 receives the digital video data DATA and timing signals from the host system. The timing signals may comprise a vertical synchronization signal, a horizontal synchronization signal, a data enable signal, and a dot clock. The host system may be an application processor of a smartphone or tablet PC, a monitor, a system on chip of a TV, etc.

The timing control unit 22 generates control signals for controlling the operation timing of the data driving unit 21 and the scan driving unit 30. The control signals may comprise a source control signal DCS for controlling the operation timing of the data driving unit 21 and a scan control signal SCS for controlling the operation timing of the scan driving unit 30.

The driving circuit 20 may be disposed in a non-display region NDA provided on one side of the display panel 10. The driving circuit 20 may be formed as an integrated circuit (IC) and mounted on the display panel 10 using a chip on glass (COG) method, a chip on plastic (COP) method, or an ultrasonic bonding method, but the present invention is not limited thereto. For example, the driving circuit 20 may be mounted on a circuit board (not illustrated) other than the display panel 10.

The data driving unit 21 may be mounted on the display panel 10 using a COG method, a COP method, or an ultrasonic bonding method, and the timing control unit 22 may be mounted on the circuit board.

The scan driving unit 30 receives a scan control signal SCS from the timing control unit 22. The scan driving unit 30 generates scan signals according to the scan control signal SCS and supplies them to the scan lines SI to Sn of the display panel 10. The scan driving unit 30 may be formed in a non-display region NDA of the display panel 10 comprising a plurality of transistors. Alternatively, the scan driving unit 30 may be formed as an integrated circuit, in which case it may be mounted on a gate flexible film attached to the other side of the display panel 10.

The circuit board may be attached to pads provided on one edge of the display panel 10 using an anisotropic conductive film. As a result, lead lines of the circuit board may be electrically connected to the pads. The circuit board may be a flexible film such as a flexible printed circuit board, a printed circuit board, or a chip on film. The circuit board may be bent to the lower part of the display panel 10. As a result, one side of the circuit board may be attached to one edge of the display panel 10, and the other side may be disposed on the lower part of the display panel 10 and connected to a system board on which a host system is mounted.

The power supply circuit 50 may generate voltages required for driving the display panel 10 from a main power applied from the system board and supply the voltages to the display panel 10. For example, the power supply circuit 50 may generate a high-potential voltage VDD and a low-potential voltage VSS for driving the light-emitting elements LD of the display panel 10 from the main power supply and supply them to the high-potential voltage line VDDL and the low-potential voltage line VSSL of the display panel 10. In addition, the power supply circuit 50 may generate and supply driving voltages for driving the driving circuit 20 and the scan driving unit 30 from the main power supply.

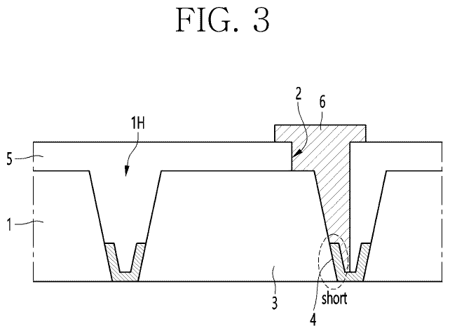

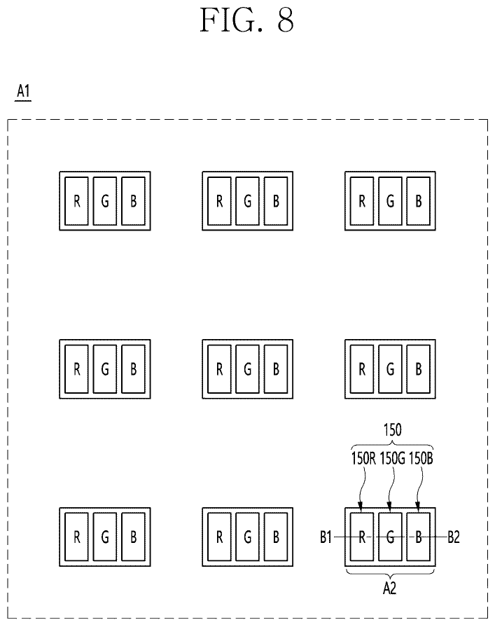

FIG. 8 is an enlarged view of the first panel region in the display device of FIG. 3.

Referring to FIG. 8, the display device 100 of the embodiment may be manufactured by mechanically and electrically connecting a plurality of panel regions such as the first panel region A1 by tiling.

The first panel region A1 may comprise a plurality of semiconductor light-emitting elements 150 disposed for each unit pixel (PX of FIG. 6).

For example, the unit pixel PX may comprise a first subpixel PX1, a second subpixel PX2, and a third subpixel PX3. For example, a plurality of red semiconductor light-emitting elements 150R may be disposed in the first subpixel PX1, a plurality of green semiconductor light-emitting elements 150G may be disposed in the second subpixel PX2, and a plurality of blue semiconductor light-emitting elements 150B may be disposed in the third subpixel PX3. The unit pixel PX may further comprise a fourth subpixel in which no semiconductor light-emitting elements are disposed, but is not limited thereto.

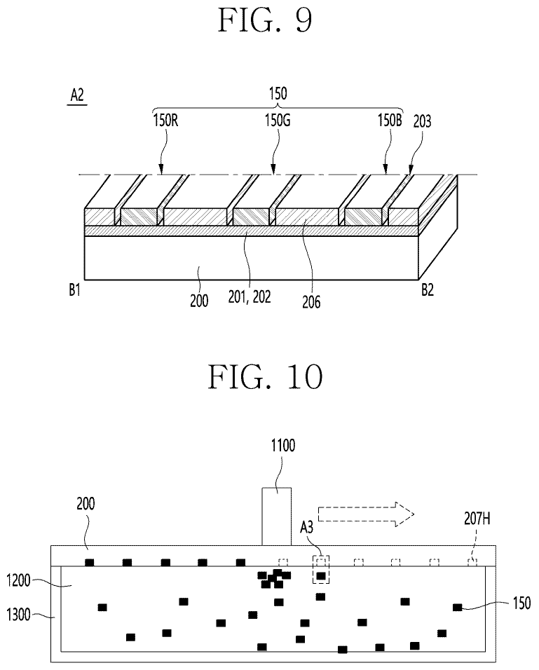

FIG. 9 is an enlarged view of the A2 region of FIG. 8.

Referring to FIG. 9, the display device 100 of the embodiment may comprise a substrate 200, assembling wiring 201 and 202, an insulating layer 206, and a plurality of semiconductor light-emitting elements 150. More components may be included than these.

The assembling wiring may comprise a first assembling wiring 201 and a second assembling wiring 202 that are spaced apart from each other. The first assembling wiring 201 and the second assembling wiring 202 may be provided to generate a dielectrophoretic force (DEP) to assemble the semiconductor light-emitting element 150. For example, the semiconductor light-emitting element 150 may be one of a lateral-type semiconductor light-emitting element, a flip-chip type semiconductor light-emitting element, and a vertical-type semiconductor light-emitting element.

The semiconductor light-emitting element 150 may comprise a red semiconductor light-emitting element 150, a green semiconductor light-emitting element 150G, and a blue semiconductor light-emitting element 150B to form a unit pixel, but is not limited thereto, and may also comprise a red phosphor and a green phosphor to implement red and green, respectively.

The substrate 200 may be a support member that supports components disposed on the substrate 200 or a protective member that protects the components.

The substrate 200 may be a rigid substrate or a flexible substrate. The substrate 200 may be formed of sapphire, glass, silicon, or polyimide. In addition, the substrate 200 may comprise a flexible material such as polyethylene naphthalate (PEN), polyethylene terephthalate (PET). In addition, the substrate 200 may be a transparent material, but is not limited thereto. The substrate 200 may function as a support substrate in a display panel, and may also function as an assembly substrate when self-assembling a light-emitting element.

The substrate 200 may be a backplane equipped with circuits, such as transistors ST and DT, capacitors Cst, and signal wiring, within the subpixels PX1, PX2, and PX3 illustrated in FIGS. 6 and 7, but is not limited thereto.

The insulating layer 206 may comprise an organic material having insulation and flexibility, such as polyimide, PAC, PEN, PET, polymer, or an inorganic material such as silicon oxide (SiO₂) or silicon nitride series (SiNₓ), and may be formed integrally with the substrate 200 to form a single substrate.

The insulating layer 206 may be a conductive adhesive layer having adhesion and conductivity, and the conductive adhesive layer may have flexibility to enable a flexible function of the display device. For example, the insulating layer 206 may be a conductive adhesive layer such as an anisotropic conductive film (ACF) or an anisotropic conductive medium, a solution containing conductive particles, etc. The conductive adhesive layer may be a layer that is electrically conductive in a direction vertical to the thickness, or electrically insulating in a direction horizontal to the thickness.

The insulating layer 206 may comprise an assembly hole 203 for inserting a semiconductor light-emitting element 150. Therefore, when self-assembling, the semiconductor light-emitting element 150 may be easily inserted into the assembly hole 203 of the insulating layer 206. The assembly hole 203 may be called an insertion hole, a fixing hole, an alignment hole, etc. The assembly hole 203 may also be called a hole.

The assembly hole 203 may be called a hole, a groove, a recess, a pocket, etc.

The assembly hole 203 may be different depending on the shape of the semiconductor light-emitting element 150. For example, the red semiconductor light-emitting element, the green semiconductor light-emitting element, and the blue semiconductor light-emitting element each have different shapes, and may have an assembly hole 203 having a shape corresponding to each shape of these semiconductor light-emitting elements. For example, the assembly hole 203 may comprise a first assembly hole for assembling the red semiconductor light-emitting element, a second assembly hole for assembling the green semiconductor light-emitting element, and a third assembly hole for assembling the blue semiconductor light-emitting element. For example, the red semiconductor light-emitting element may have a circular shape, the green semiconductor light-emitting element may have a first oval shape having a first minor axis and a first major axis, and the blue semiconductor light-emitting element may have a second oval shape having a second minor axis and a second major axis, but is not limited thereto. The second major axis of the second oval shape of the blue semiconductor light-emitting element may be greater than the second major axis of the first oval shape of the green semiconductor light-emitting element, and the second minor axis of the second oval shape of the blue semiconductor light-emitting element may be smaller than the first minor axis of the first oval shape of the green semiconductor light-emitting element.

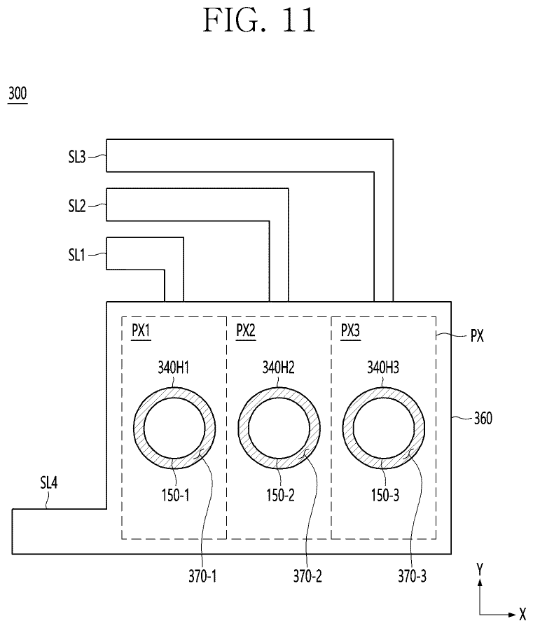

Meanwhile, the method of mounting the semiconductor light-emitting element 150 on the substrate 200 may comprise, for example, a self-assembly method (FIG. 10) and a transfer method.

FIG. 10 is a drawing illustrating an example in which a light-emitting element according to an embodiment is assembled on a substrate by a self-assembly method.

Based on FIG. 10, an example in which a semiconductor light-emitting element according to an embodiment is assembled on a display panel by a self-assembly method using an electromagnetic field will be described.

The assembly substrate 200 described below may also function as a panel substrate 200a in a display device after assembling the light-emitting element, but the embodiment is not limited thereto.

Referring to FIG. 10, the semiconductor light-emitting element 150 may be put into a chamber 1300 filled with a fluid 1200, and the semiconductor light-emitting element 150 may be moved to the assembly substrate 200 by a magnetic field generated from the assembly device 1100. At this time, the light-emitting element 150 adjacent to the assembly hole 207H of the assembly substrate 200 may be assembled into the assembly hole 207H by the DEP force caused by the electric field of the assembling wirings. The fluid 1200 may be water such as ultrapure water, but is not limited thereto. The chamber may be called a tank, a container, a vessel, etc.

After the semiconductor light-emitting element 150 is put into the chamber 1300, the assembly substrate 200 may be disposed on the chamber 1300. According to an embodiment, the assembly substrate 200 may be put into the chamber 1300.

The semiconductor light-emitting element 150 may comprise a magnetic layer (not illustrated) having a magnetic substance. The magnetic layer may comprise a metal having magnetism, such as nickel (Ni). Since the semiconductor light-emitting element 150 put into the fluid comprises the magnetic layer, it may move to the assembly substrate 200 by a magnetic field generated from the assembly device 1100. The magnetic layer may be disposed on the upper side or lower side or both sides of the light-emitting element.

The semiconductor light-emitting element 150 may comprise a passivation layer surrounding the upper surface and the side surface thereof. The passivation layer may be formed by forming an inorganic insulator, such as silica or alumina, by PECVD, LPCVD, sputtering deposition, etc. In addition, the passivation layer may be formed by spin coating an organic material, such as a photoresist or a polymer material.

The semiconductor light-emitting element 150 may comprise a first conductivity type semiconductor layer, a second conductivity type semiconductor layer, and an active layer disposed therebetween. The first conductivity type semiconductor layer may be an n-type semiconductor layer, and the second conductivity type semiconductor layer may be a p-type semiconductor layer, but is not limited thereto. The first conductivity type semiconductor layer, the second conductivity type semiconductor layer, and the active layer disposed therebetween may constitute a light-emitting portion. The light-emitting portion may be called a light-emitting layer, a light-emitting region, etc.

The first electrode (layer) may be disposed below the first conductivity type semiconductor layer, and the second electrode (layer) may be disposed on the second conductivity type semiconductor layer. To this end, a part of the first conductivity type semiconductor layer or the second conductivity type semiconductor layer may be exposed to the outside. Accordingly, after the semiconductor light-emitting element 150 is assembled on the assembly substrate 200, a part of the passivation layer may be etched in the manufacturing process of the display device.

The first electrode may comprise at least one or more layer. For example, the first electrode may comprise an ohmic layer, a reflective layer, a magnetic layer, a conductive layer, an anti-oxidation layer, an adhesive layer, etc. The ohmic layer may comprise Au, AuBe, etc. The reflective layer may comprise Al, Ag, etc. The magnetic layer may comprise Ni, Co, etc. The conductive layer may comprise Cu, etc. The anti-oxidation layer may comprise Mo, etc. The adhesive layer may comprise Cr, Ti, etc.

The second electrode may comprise a transparent conductive layer. For example, the second electrode may comprise ITO, IZO, etc.

The assembly substrate 200 may comprise a pair of first assembling wirings 201 and second assembling wirings 202 corresponding to each of the semiconductor light-emitting elements 150 to be assembled. Each of the first assembling wirings 201 and the second assembling wirings 202 may be formed by laminating a single metal or a metal alloy, a metal oxide, etc. in multiple layers. For example, each of the first assembling wiring 201 and the second assembling wiring 202 may be formed by comprising at least one of Cu, Ag, Ni, Cr, Ti, Al, Rh, Pd, Ir, Ru, Mg. Zn, Pt, Au, and Hf, but is not limited thereto.

The first assembling wiring 201 and the second assembling wiring 202 may form an electric field when an AC voltage is applied, and the semiconductor light-emitting element 150 inserted into the assembly hole 207H may be fixed by the DEP force caused by the electric field. The gap between the first assembling wiring 201 and the second assembling wiring 202 may be smaller than the width of the semiconductor light-emitting element 150 and the width of the assembly hole 207H, and the assembly position of the semiconductor light-emitting element 150 may be fixed more precisely using the electric field.

An insulating layer 215 may be formed on the first assembling wiring 201 and the second assembling wiring 202 to protect the first assembling wiring 201 and the second assembling wiring 202 from the fluid 1200 and prevent leakage of current flowing in the first assembling wiring 201 and the second assembling wiring 202. For example, the insulating layer 215 may be formed as a single layer or multiple layers of an inorganic insulator such as silica or alumina or an organic insulator. The insulating layer 215 may have a minimum thickness to prevent damage to the first assembling wiring 201 and the second assembling wiring 202 during assembly of the semiconductor light-emitting element 150, and may have a maximum thickness to stably assemble the semiconductor light-emitting element 150.

A partition wall 207 may be formed on the upper part of the insulating layer 215. A part of the partition wall 207 may be positioned at the upper part of the first assembling wiring 201 and the second assembling wiring 202, and the remaining regions may be positioned at the upper part of the assembly substrate 200.

Meanwhile, when manufacturing the assembly substrate 200, a part of the partition wall formed at the upper part of the insulating layer 215 may be removed, thereby forming assembly holes 207H in which each of the semiconductor light-emitting elements 150 is coupled and assembled to the assembly substrate 200.

The assembly substrate 200 has assembly holes 207H formed in which the semiconductor light-emitting elements 150 are coupled, and a surface on which the assembly holes 207H are formed may be in contact with the fluid 1200. The assembly holes 207H may guide the exact assembly positions of the semiconductor light-emitting elements 150.

Meanwhile, the assembly hole 207H may have a shape and size corresponding to the shape of the semiconductor light-emitting element 150 to be assembled at the corresponding position. Accordingly, it is possible to prevent another semiconductor light-emitting element from being assembled in the assembly hole 207H or a plurality of semiconductor light-emitting elements from being assembled.

Referring back to FIG. 10, after the assembly substrate 200 is disposed in the chamber, the assembly device 1100 applying a magnetic field may move along the assembly substrate 200. The assembly device 1100 may be a permanent magnet or an electromagnet.

The assembly device 1100 may move in contact with the assembly substrate 200 to maximize a region affected by the magnetic field within the fluid 1200. Depending on the embodiment, the assembly device 1100 may comprise a plurality of magnetic substances or may comprise magnetic substances of a size corresponding to the assembly substrate 200. In this instance, the movement distance of the assembly device 1100 may be limited within a predetermined range.

The semiconductor light-emitting element 150 within the chamber 1300 may move toward the assembly device 1100 and the assembly substrate 200 by the magnetic field generated by the assembly device 1100.

The semiconductor light-emitting element 150 may be fixed by entering the assembly hole 207H by the DEP force formed by the electric field between the assembling wirings 201 and 202 while moving toward the assembly device 1100.

Specifically, the first and second assembling wirings 201 and 202 form an electric field by an AC power source, and the DEP force may be formed between the assembling wirings 201 and 202 by this electric field. The semiconductor light-emitting element 150 may be fixed to the assembly hole 207H on the assembly substrate 200 by this DEP force.

At this time, a predetermined solder layer (not illustrated) may be formed between the light-emitting element 150 assembled on the assembly hole 207H of the assembly substrate 200 and the assembling wirings 201 and 202 to improve the bonding strength of the light-emitting element 150.

In addition, a molding layer (not illustrated) may be formed in the assembly hole 207H of the assembly substrate 200 after assembly. The molding layer may be a transparent resin or a resin containing a reflective material or a scattering material.

Since the time required for each semiconductor light-emitting element to be assembled on the substrate may be drastically shortened by the self-assembly method using the electromagnetic field described above, a large-area high-pixel display may be implemented more quickly and economically.

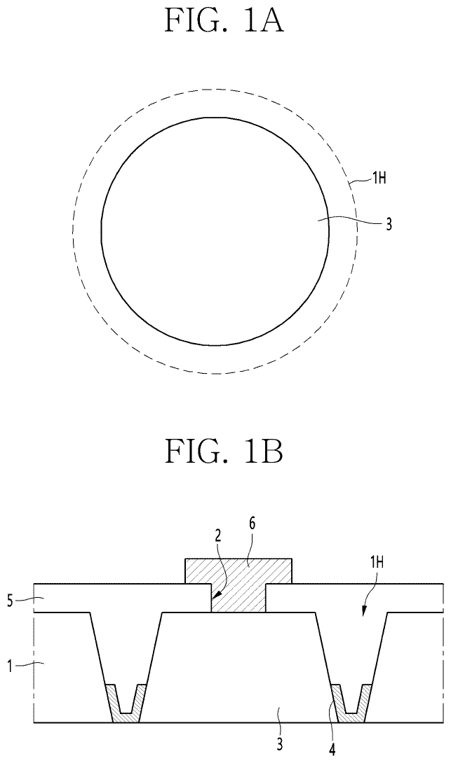

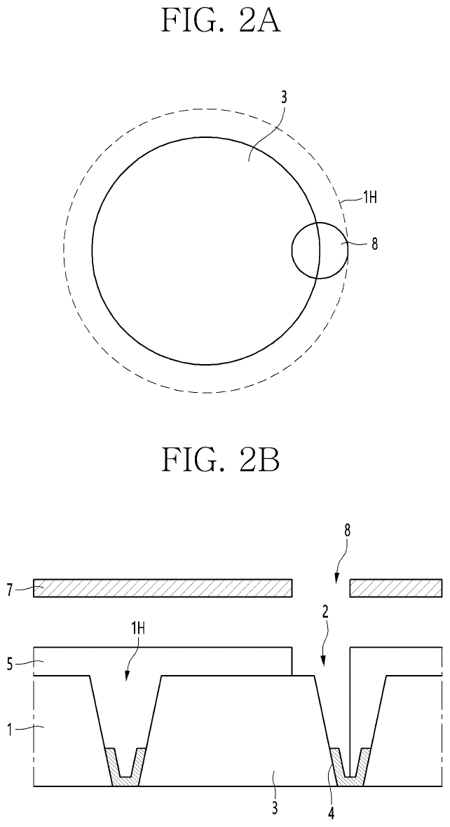

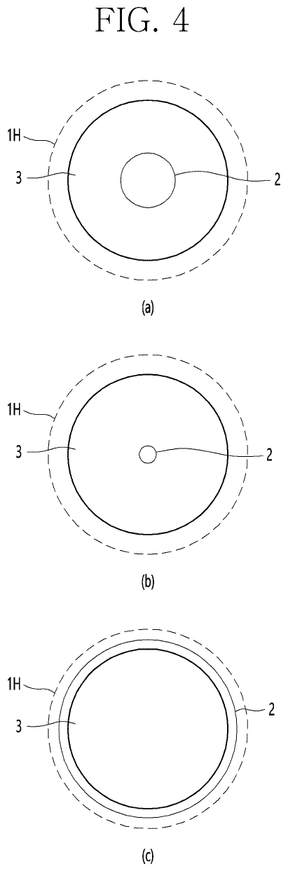

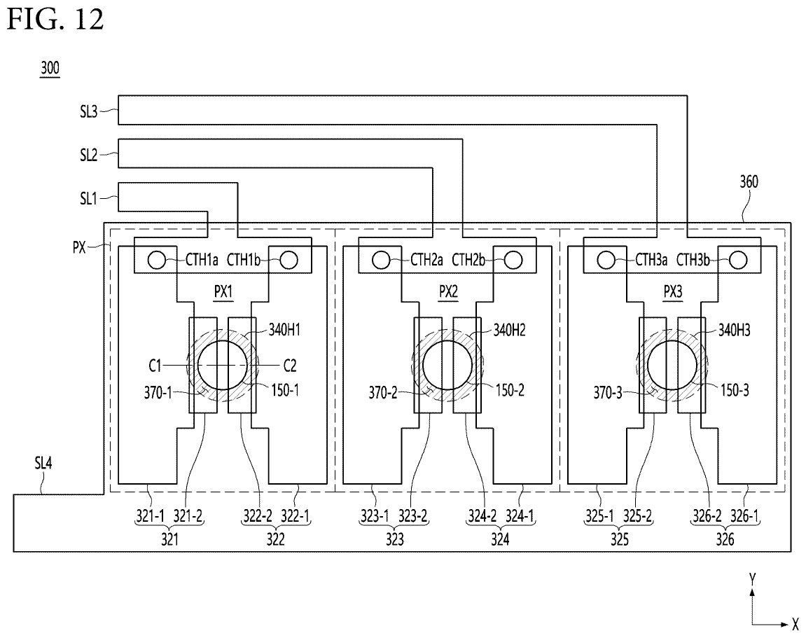

Hereinafter, various embodiments for solving the above-described problem will be described with reference to FIGS. 11 to 25. Any description omitted below may be easily understood from the descriptions described above with respect to FIGS. 1 to 10 and the corresponding drawings.

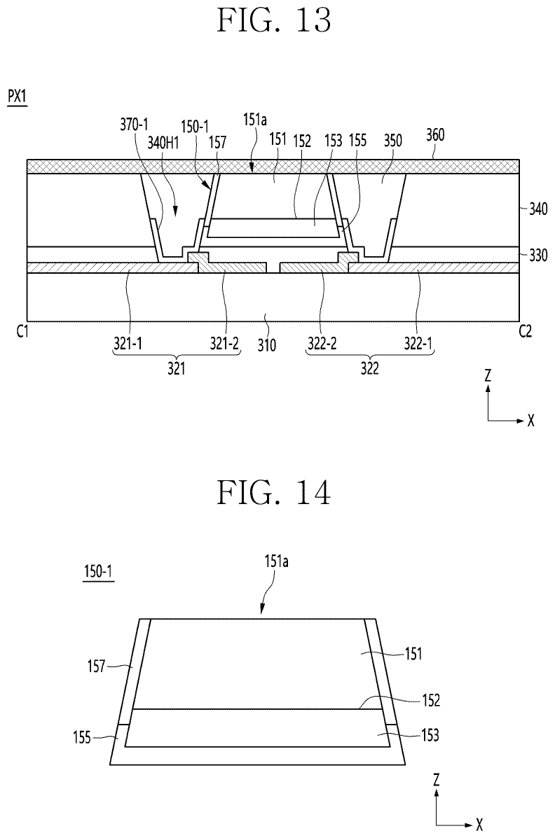

FIG. 11 is a plan view illustrating a display device according to an embodiment. FIG. 12 is a plan view illustrating a display device according to an embodiment in more detail.

As illustrated in FIG. 11 and FIG. 12, the unit pixel PX may comprise a first subpixel PX1, a second subpixel PX2, and a third subpixel PX3.

The display device 300 according to the embodiment may comprise at least one first semiconductor light-emitting element 150-1, at least one second semiconductor light-emitting element 150-2, and at least one third semiconductor light-emitting element 150-3 to display an image.

At least one first semiconductor light-emitting element 150-1 may be disposed in the first subpixel PX1, at least one second semiconductor light-emitting element 150-2 may be disposed in the second subpixel PX2, and at least one third semiconductor light-emitting element 150-3 may be disposed in the third subpixel PX3.

The first subpixel PX1 may comprise a first assembly hole 340H1, the second subpixel PX2 may comprise a second assembly hole 340H2, and the third subpixel PX3 may comprise a third assembly hole 340H3. The first semiconductor light-emitting element 150-1 may be disposed in the first assembly hole 340H1 of the first subpixel PX1, the second semiconductor light-emitting element 150-2 may be disposed in the second assembly hole 340H2 of the second subpixel PX2, and the third semiconductor light-emitting element 150-3 may be disposed in the third assembly hole 340H3 of the third subpixel PX3.

The display device 300 according to the embodiment may comprise an electrode wiring 360. The electrode wiring 360 may be disposed on an entire region of the unit pixel PX. That is, the electrode wiring 360 may be disposed on the first subpixel PX1, the second subpixel PX2, and the third subpixel PX3. For example, the electrode wiring 360 may be disposed on the first semiconductor light-emitting element 150-1 of the first subpixel PX1, the second semiconductor light-emitting element 150-2 of the second subpixel PX2, and the third semiconductor light-emitting element 150-3 of the third subpixel PX3.

The electrode wiring 360 may have a plate shape. For example, a lower surface and/or an upper surface of the electrode wiring 360 may have a horizontal plane. For example, the electrode wiring 360 having a plate shape may be formed by depositing a metal film over the entire region of the unit pixel PX. Therefore, a separate patterning process is not required after the deposition, so that the process is simple and the process time can be shortened.

The electrode wiring 360 may be a cathode electrode. The electrode wiring 360 may be commonly connected to the first semiconductor light-emitting element 150-1, the second semiconductor light-emitting element 150-2, and the third semiconductor light-emitting element 150-3. For example, a low-potential voltage (VSS of FIG. 6) supplied from a low-potential voltage line (VSSL of FIG. 7) may be supplied to each of the first semiconductor light-emitting element 150-1, the second semiconductor light-emitting element 150-2, and the third semiconductor light-emitting element 150-3 through the electrode wiring 360. For example, the low-potential voltage may be 0 V or a lower voltage.

The display device 300 according to the embodiment may comprise a plurality of connection electrodes 370-1, 370-2, and 370-3. The plurality of connection electrodes may comprise a first connection electrode 370-1, a second connection electrode 370-2, and a third connection electrode 370-3. The first connection electrode 370-1 may be disposed on a side portion of the first semiconductor light-emitting element 150-1, the second connection electrode 370-2 may be disposed on a side portion of the second semiconductor light-emitting element 150-2, and the third connection electrode 370-3 may be disposed on a side portion of the third semiconductor light-emitting element 150-3.

The first connection electrode 370-1 may be disposed in the first assembly hole 340H1 of the first subpixel PX1. For example, the first connection electrode 370-1 may be disposed around the first semiconductor light-emitting element 150-1 in the first assembly hole 340H1. The second connection electrode 370-2 may be disposed in the second assembly hole 340H2 of the second subpixel PX2. For example, the second connection electrode 370-2 may be disposed around the second semiconductor light-emitting element 150-2 in the second assembly hole 340H2. The third connection electrode 370-3 may be disposed in the third assembly hole 340H3 of the third subpixel PX3. For example, the third connection electrode 370-3 may be disposed around the third semiconductor light-emitting element 150-3 in the third assembly hole 340H3.

Meanwhile, the display device 300 according to the embodiment may comprise a plurality of signal lines SL1 to SL4. The plurality of signal lines may comprise a first signal line SL1, a second signal line SL2, a third signal line SL3, and a fourth signal line SL4.

The first signal line SL1 may be connected to the first connection electrode 370-1 of the first subpixel PX1, the second signal line SL2 may be connected to the second connection electrode 370-2 of the second subpixel PX2, and the third signal line SL3 may be connected to the third connection electrode 370-3 of the third subpixel PX3. For example, the first signal line SL1 may be connected to the first connection electrode 370-1 connected to the side portion of the first semiconductor light-emitting element 150-1 in the first subpixel PX1. For example, the second signal line SL2 may be connected to the second connection electrode 370-2 connected to the side portion of the second semiconductor light-emitting element 150-2 in the second subpixel PX2. For example, the third signal line SL3 may be connected to the third connection electrode 370-3 connected to the side portion of the third semiconductor light-emitting element 150-3 in the third subpixel PX3.

The first signal line SL1, the second signal line SL2, and the third signal line SL3 may be connected to the first data line D1, the second data line D2, and the third data line D3 via the scan transistor ST and the driving transistor DT, respectively, as illustrated in FIGS. 6 and 7. For example, the first signal line SL1, the second signal line SL2, and the third signal line SL3 may be connected to the drain electrode of the driving transistor DT, respectively, and the high-potential voltage line VDDL, which supplies the high-potential voltage VDD, may be connected to the source electrode of the driving transistor DT.

The fourth signal line SL4 may be connected to the electrode wiring 360, which is commonly connected to the upper side of each of the first semiconductor light-emitting element 150-1, the second semiconductor light-emitting element 150-2, and the third semiconductor light-emitting element 150-3. In addition, the fourth signal line SL4 may be connected to the low-potential voltage line VSSL. Accordingly, the low-potential voltage (VSS in FIG. 6) may be supplied to each of the first semiconductor light-emitting element 150-1, the second semiconductor light-emitting element 150-2, and the third semiconductor light-emitting element 150-3 via the low-potential voltage line VSSL, the fourth signal line SL4, and the electrode wiring 360.

As an example, the fourth signal line SL4 may be formed integrally with the electrode wiring 360. In this instance, the fourth signal line SL4 and the electrode wiring 360 may be positioned on the same horizontal plane. For example, the fourth signal line SL4 and the electrode wiring 360 may be formed simultaneously using the same patterning process. For example, a metal film may be deposited and patterned on the substrate 310, so that the electrode wiring 360 and the fourth signal line SL4 extending from the electrode wiring 360 may be simultaneously formed on the first subpixel PX1, the second subpixel PX2, and the third subpixel PX3.

As another example, the fourth signal line SL4 may not be formed integrally with the electrode wiring 360. In such a case, the fourth signal line SL4 and the electrode wiring 360 may be disposed on different layers. That is, the fourth signal line SL4 may be electrically connected to the electrode wiring 360 through a contact hole.

The same high-potential voltage VDD may be supplied to the high-potential voltage line VDDL connected to each of the first subpixel PX1, the second subpixel PX2, and the third subpixel PX3. The same low-potential voltage VSS may be supplied to the low-potential voltage line VSSL connected to each of the first subpixel PX1, the second subpixel PX2, and the third subpixel PX3.

In this instance, the first subpixel PX1, the second subpixel PX2, and the third subpixel PX3 each have the same potential value, that is, a potential value corresponding to a potential difference between the high potential voltage VDD and the low potential voltage VSS, and the luminance of light of the first semiconductor light-emitting element 150-1 of the first subpixel PX1, the second semiconductor light-emitting element 150-2 of the second subpixel PX2, and the third semiconductor light-emitting element 150-3 of the third subpixel PX3 may be determined according to a first data voltage, a second data voltage, and a third data voltage, respectively. That is, the luminance of light of the first semiconductor light-emitting element 150-1, the second semiconductor light-emitting element 150-2, and the third semiconductor light-emitting element 150-3 may be determined by the driving current flowing in the driving transistor DT of the first subpixel PX1, the second subpixel PX2, and the third subpixel PX3 according to the first data voltage, the second data voltage, and the third data voltage, respectively.

For example, a first driving current flows in the driving transistor DT of the first subpixel PX1 according to the first data voltage, and the first semiconductor light-emitting element 150-1 may emit first light having a first luminance corresponding to the first driving current. For example, a second driving current flows in the driving transistor DT of the second subpixel PX2 according to the second data voltage, and the second semiconductor light-emitting element 150-2 may emit second light having a second luminance corresponding to the second driving current. For example, a third driving current may flow to the driving transistor DT of the third subpixel PX3 according to the third data voltage, and the third semiconductor light-emitting element 150-3 may emit third light having a third luminance corresponding to the third driving current. For example, the first light may be red light, the second light may be green light, and the third light may be blue light.

Meanwhile, since the luminance is determined by the driving current, when the driving current is to be increased, the potential difference between the low-potential voltage VSS and the high-potential voltage VDD may be increased. For example, when the low-potential voltage VSS is 0 V, the driving current may be increased by increasing the high-potential voltage VDD, and thus the luminance may also be increased. In other words, the luminance may be adjusted by adjusting the potential difference between the low-potential voltage VSS and the high-potential voltage VDD.

For example, the first semiconductor light-emitting element 150-1 may be formed of a compound semiconductor material comprising GaAs to emit red light, but is not limited thereto. For example, the second semiconductor light-emitting element 150-2 and the third semiconductor light-emitting element 150-3 may be formed of a compound semiconductor material comprising GaN to emit green light and blue light, respectively, but is not limited thereto.

Meanwhile, the electrode wiring 360 commonly connected to the first semiconductor light-emitting element 150-1, the second semiconductor light-emitting element 150-2, and the third semiconductor light-emitting element 150-3 may be supplied with a low-potential voltage VSS, and the source electrode of the driving transistor DT may be supplied with a high-potential voltage VDD. In this instance, as described above, the light intensity, i.e., luminance, of the first semiconductor light-emitting element 150-1, the second semiconductor light-emitting element 150-2, and the third semiconductor light-emitting element 150-3 may vary depending on the magnitude of the first data voltage, the second data voltage, and the third data voltage supplied to the first data line DI, the second data line D2, and the third data line D3, respectively. The first data voltage may be a red data voltage, the second data voltage may be a green data voltage, and the third data voltage may be a blue data voltage, but is not limited thereto.

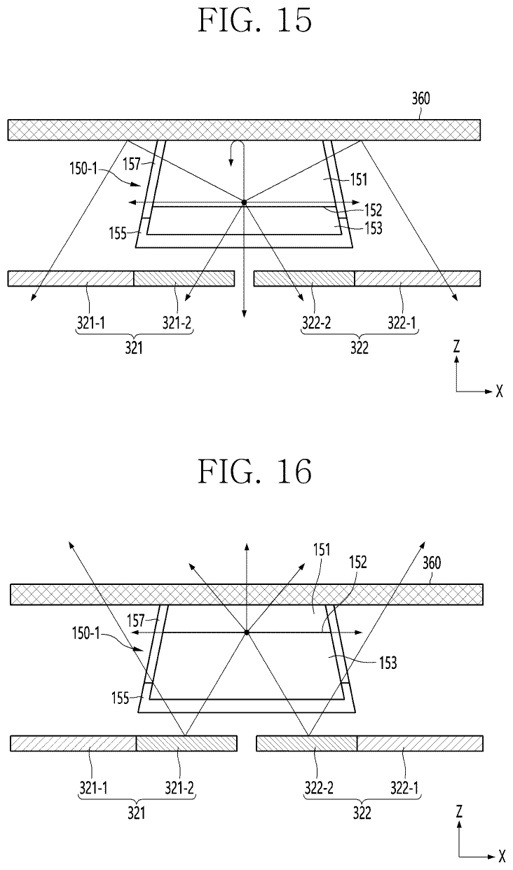

FIG. 13 is a cross-sectional view taken along the line C1-C2 in the display device according to the embodiment of FIG. 12.

FIG. 13 illustrates the first subpixel PX1, but the second subpixel PX2 and the third subpixel PX3 also have a structure similar to the first subpixel PX1, and thus may be easily understood from the following description of the first subpixel PX1.

Referring to FIGS. 11 to 13, the display device 300 according to an embodiment may comprise a substrate 310, first assembling wirings 321, 323, and 325, second assembling wirings 322, 324, and 326, a partition wall 340, a plurality of semiconductor light-emitting elements 150-1, 150-2, and 150-3, a plurality of connection electrodes 370-1, 370-2, and 370-3, and an electrode wiring 360. The display device 300 according to an embodiment may comprise more components than these.

The substrate 310 serves to support components disposed thereon, and since it has been described above, a detailed description thereof will be omitted.

A plurality of subpixels PX1, PX2, and PX3 may be defined on the substrate 310. Although the drawing illustrates that the first subpixel PX1, the second subpixel PX2, and the third subpixel PX3 are arranged along the second direction Y, he present invention is not limited thereto.

A first subpixel column comprising a plurality of first subpixels PX1, a second subpixel column comprising a plurality of second subpixels PX2, and a third subpixel column comprising a plurality of third subpixels PX3 may be arranged parallel to each other along the second direction Y.

At least one assembly hole 340H1, 340H2, and 340H3 may be provided in each of the first subpixel PX1, the second subpixel PX2, and the third subpixel PX3.

Through the self-assembly process, the plurality of semiconductor light-emitting elements 150-1, 150-2 and 150-3 may be assembled into the assembly holes 340H1, 340H2 and 340H3, respectively, by the DEP forces formed between the first assembling wirings 321, 323 and 325 and the second assembling wirings 322, 324 and 326 in the plurality of subpixels PX1, PX2 and PX3, respectively.

For example, the first semiconductor light-emitting element 150-1 may be assembled into the first assembly hole 340H1 by the DEP force formed between the first assembling wiring 321 and the second assembling wiring 322 provided in the first subpixel PX1. For example, the second semiconductor light-emitting element 150-2 may be assembled into the second assembly hole 340H2 by the DEP force formed between the first assembling wiring 323 and the second assembling wiring 324 provided in the second subpixel PX2. For example, the third semiconductor light-emitting element 150-3 may be assembled into the third assembly hole 340H3 by the DEP force formed between the first assembling wiring 325 and the second assembling wiring 326 provided in the third subpixel PX3.

The size of the assembly hole 340H1, 340H2 and 340H3 may be determined by taking into consideration a tolerance margin for forming the assembly hole 340H1, 340H2 and 340H3 and a margin for easily assembling the semiconductor light-emitting element 150-1, 150-2 and 150-3 within the assembly hole 340H1, 340H2 and 340H3. For example, the size of the assembly hole 340H1, 340H2 and 340H3 may be greater than the size of the semiconductor light-emitting element 150-1, 150-2 and 150-3. For example, when the semiconductor light-emitting element 150-1, 150-2 and 150-3 is assembled at the center of the assembly hole 340H1, 340H2 and 340H3, the distance between the outer side surface of the semiconductor light-emitting element 150-1, 150-2 and 150-3 and the inner side surface of the assembly hole 340H1, 340H2 and 340H3 may be 2 μm or less, but is not limited thereto.

For example, the assembly hole 340H1, 340H2 and 340H3 may have a shape corresponding to the shape of the semiconductor light-emitting element 150-1, 150-2 and 150-3. For example, when the semiconductor light-emitting element 150-1, 150-2 and 150-3 has a circular shape, the assembly hole 340H1, 340H2 and 340H3 may have also a circular shape. For example, when the semiconductor light-emitting element 150-1, 150-2, and 150-3 is rectangular, the assembly hole 340H1, 340H2, and 340H3 may also be rectangular.

As an example, the assembly holes 340H1, 340H2, and 340H3 in the first subpixel PX1, the second subpixel PX2, and the third subpixel PX3, respectively, may have the same shape, i.e., a circular shape. In this instance, the first semiconductor light-emitting element 150-1 disposed in the first subpixel PX1, the second semiconductor light-emitting element 150-2 disposed in the second subpixel PX2, and the third semiconductor light-emitting element 150-3 disposed in the third subpixel PX3 may have shapes corresponding to the assembly holes 340H1, 340H2, and 340H3, i.e., a circular shape.

In this way, when the assembly holes 340H1, 340H2 and 340H3 of the first subpixel PX1, the second subpixel PX2 and the third subpixel PX3 have the same shape, the first semiconductor light-emitting element 150-1, the second semiconductor light-emitting element 150-2 and the third semiconductor light-emitting element 150-3 may be sequentially assembled into the assembly holes 340H1, 340H2 and 340H3 of the corresponding subpixels PX1, PX2 and PX3, respectively, but is not limited thereto.

For example, the first semiconductor light-emitting element 150-1 may be assembled into the first assembly hole 340H1 of the first subpixel PX1 of the substrate 310, the second semiconductor light-emitting element 150-2 may be assembled into the second assembly hole 340H2 of the second subpixel PX2 of the substrate 310, and the third semiconductor light-emitting element 150-3 may be assembled into the third assembly hole 340H3 of the third subpixel PX3 of the substrate 310. In this instance, the shapes of the first semiconductor light-emitting element 150-1, the second semiconductor light-emitting element 150-2, and the third semiconductor light-emitting element 150-3 may be the same, but are not limited thereto. Each of the assembly holes 340H1, 340H2, and 340H3 has a shape corresponding to a shape of each of the first semiconductor light-emitting element 150-1, the second semiconductor light-emitting element 150-2, and the third semiconductor light-emitting element 150-3, but may have a size greater than each of the first semiconductor light-emitting element 150-1, the second semiconductor light-emitting element 150-2, and the third semiconductor light-emitting element 150-3.

As another example, although not illustrated, the assembly holes 340H1, 340H2, and 340H3 in each of the first subpixel PX1, the second subpixel PX2, and the third subpixel PX3 may have different shapes.

For example, the first assembly hole 340H1 in the first subpixel PX1 may have a circular shape, the second assembly hole 340H2 in the second subpixel PX2 may have a first oval shape having a first minor axis and a first major axis, and the third assembly hole 340H3 in the third subpixel PX3 may have a second oval shape having a second minor axis smaller than the first minor axis and a second major axis greater than the first major axis. In this instance, the first semiconductor light-emitting element 150-1 may have a shape corresponding to the first assembly hole 340H1 of the first subpixel PX1, that is, a circular shape, the second semiconductor light-emitting element 150-2 may have a shape corresponding to the second assembly hole 340H2 of the second subpixel PX2, that is, a first oval shape, and the third semiconductor light-emitting element 150-3 may have a shape corresponding to the third assembly hole 340H3 of the third subpixel PX3, that is, a second oval shape.

By means of the assembly holes 340H1, 340H2 and 340H3 having different shapes and the first to third semiconductor light-emitting elements 150-1, 150-2 and 150-3 having shapes corresponding to the assembly holes 340H1, 340H2 and 340H3, the first to third semiconductor light-emitting elements 150-1, 150-2 and 150-3 may be simultaneously assembled into the corresponding assembly holes 340H1, 340H2 and 340H3 during self-assembly. That is, even if the first semiconductor light-emitting element 150-1, the second semiconductor light-emitting element 150-2, and the third semiconductor light-emitting element 150-3 are mixed in the fluid 1200 for self-assembly, the semiconductor light-emitting elements 150-1, 150-2, and 150-3 corresponding to the assembly holes 340H1, 340H2, and 340H3 of the first subpixel PX1, the second subpixel PX2, and the third subpixel PX3 on the substrate 310 may be assembled.

For example, the first semiconductor light-emitting element 150-1 having a shape corresponding to the shape of the first assembly hole 340H1 of the first subpixel PX1 may be assembled into the first assembly hole 340H1. At the same time, a second semiconductor light-emitting element 150-2 having a shape corresponding to the shape of the second assembly hole 340H2 of the second subpixel PX2 may be assembled into the second assembly hole 340H2. At the same time, a third semiconductor light-emitting element 150-3 having a shape corresponding to the shape of the third assembly hole 340H3 of the third subpixel PX3 may be assembled into the third assembly hole 340H3. Accordingly, since the first semiconductor light-emitting element 150-1, the second semiconductor light-emitting element 150-2, and the third semiconductor light-emitting element 150-3 having different shapes are assembled into the assembly holes 340H1, 340H2, and 340H3 corresponding to their shapes, assembly defect can be prevented.

Meanwhile, the plurality of semiconductor light-emitting elements may comprise a first semiconductor light-emitting element 150-1, a second semiconductor light-emitting element 150-2, and a third semiconductor light-emitting element 150-3. For example, the first semiconductor light-emitting element 150-1 may be disposed in the first assembly hole 340H1 of the first subpixel PX1, the second semiconductor light-emitting element 150-2 may be disposed in the second assembly hole 340H2 of the second subpixel PX2, and the third semiconductor light-emitting element 150-3 may be disposed in the third assembly hole 340H3 of the third subpixel PX3.

Since the structures of the first semiconductor light-emitting element 150-1, the second semiconductor light-emitting element 150-2, and the third semiconductor light-emitting element 150-3 are similar or identical, the following description will focus on the first semiconductor light-emitting element 150-1. The second semiconductor light-emitting element 150-2 and the third semiconductor light-emitting element 150-3 may be easily understood from the first semiconductor light-emitting element 150-1 described below.

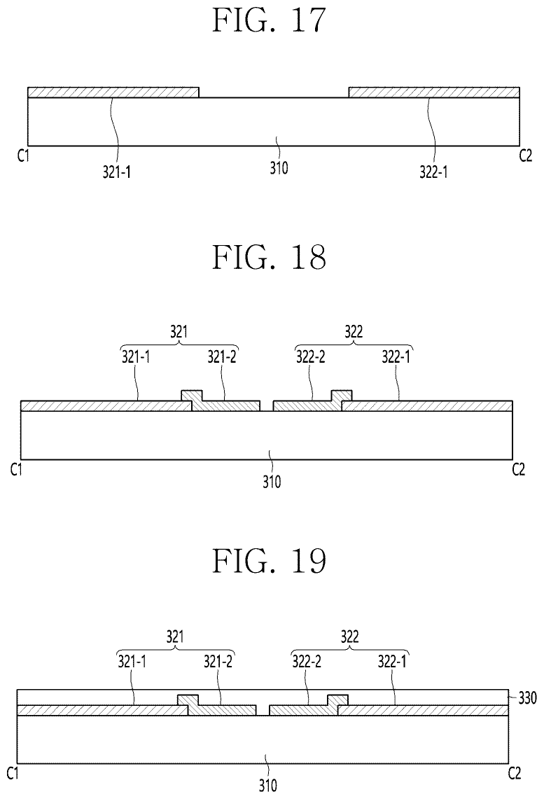

As illustrated in FIG. 14, the first semiconductor light-emitting element 150-1 may comprise a second conductivity type semiconductor layer 153, an active layer 152, a first conductivity type semiconductor layer 151, a passivation layer 157, and a side electrode 155. The second conductivity type semiconductor layer, the active layer 152, and the first conductivity type semiconductor layer 151 may form a light-emitting layer.

The active layer 152 may be disposed on an upper surface of the second conductivity type semiconductor layer 153, and the first conductivity type semiconductor layer 151 may be disposed on an upper surface of the active layer 152. The second conductivity type semiconductor layer 153 may comprise a p-type dopant, and the first conductivity type semiconductor layer 151 may comprise an n-type dopant. The passivation layer 157 may surround the perimeter of the light-emitting layers 151 to 153.

Although not illustrated, an upper electrode comprising an ohmic layer for ohmic formation may be disposed on the first conductivity type semiconductor layer 151, but is not limited thereto.

The side electrode 155 may be disposed on a side portion of the light-emitting layers 151 to 153. The side electrode 155 may extend from a lower side of the light-emitting layers 151 to 153 and be disposed on the side portion of the light-emitting layers 151 to 153. The side electrode 155 may be disposed along the perimeter of the side portion of the light-emitting layers 151 to 153, but is not limited thereto. For example, the side electrode 155 may be disposed along the perimeter of the side portion of the second conductivity type semiconductor layer 153. The side electrode 155 may be in contact with the passivation layer 157 at the side portion of the light-emitting layers 151 to 153. Therefore, the light-emitting layers 151 to 153 may be protected by the passivation layer 157 and the side electrode 155. Since the height of the side electrode 155 disposed on the side portion of the light-emitting layers 151 to 153 is smaller than the height of the active layer 152, an electrical short between the side electrode 155 and the active layer 152 can be prevented. Here, the height may be based on the lower surface of the light-emitting layers 151 to 153.

Meanwhile, the first semiconductor light-emitting element 150-1 may have an inclined surface 154 such that the size of the lower side thereof is greater than the size of the upper side. The inclined surface 154 may be a side surface of the light-emitting layer 151 to 153 or a side surface of the passivation layer 157. For example, the inclined surface 154 may be such that the size of the lower surface of the light-emitting layer 151 to 153 is greater than the size of an upper surface 151a. In this instance, since the passivation layer 157 is disposed on the inclined surface 154 of the light-emitting layer 151 to 153, the passivation layer 157 may also have an inclined surface.

Meanwhile, the partition wall 340 may comprise a plurality of assembly holes 340H1, 340H2, and 340H3. The plurality of assembly holes 340H1, 340H2 and 340H3 may comprise a first assembly hole 340H1 in the first subpixel PX1, a second assembly hole 340H2 in the second subpixel PX2 and a third assembly hole 340H3 in the third subpixel PX3.

The first assembly hole 340H1, the second assembly hole 340H2 and the third assembly hole 340H3 may be a groove, a recess, a groove, or a dent having a predetermined depth, respectively.

As described above, the first semiconductor light-emitting element 150-1, the second semiconductor light-emitting element 150-2 and the third semiconductor light-emitting element 150-3 may be assembled into the first assembly hole 340H1, the second assembly hole 340H2 and the third assembly hole 340H3, respectively, using a self-assembly method.

The upper surfaces of the first semiconductor light-emitting element 150-1, the second semiconductor light-emitting element 150-2 and the third semiconductor light-emitting element 150-3, which are respectively disposed in the first assembly hole 340H1, the second assembly hole 340H2 and the third assembly hole 340H3, may be the same as or higher than the upper surface of the partition wall 340.

Meanwhile, the first subpixel PX1, the second subpixel PX2 and the third subpixel PX3 may comprise the first assembling wirings 321, 323 and 325 and the second assembling wirings 322, 324 and 326, respectively.

The first assembling wirings 321, 323 and 325 may be respectively disposed in the first subpixel PX1, the second subpixel PX2 and the third subpixel PX3 of the substrate 310. The second assembling wirings 322, 324 and 326 may be disposed in the first subpixel PX1, the second subpixel PX2 and the third subpixel PX3 of the substrate 310, respectively.

The first semiconductor light-emitting element 150-1, the second semiconductor light-emitting element 150-2 and the third semiconductor light-emitting element 150-3 may be disposed in the first assembly hole 340H1 of the first subpixel PX1, the second assembly hole 340H2 of the second subpixel PX2 and the third assembly hole 340H3 of the third subpixel PX3, respectively, by the DEP force between the first assembling wirings 321, 323 and 325 and the second assembling wirings 322, 324 and 326. That is, the first assembling wirings 321, 323 and 325 and the second assembling wirings 322, 324 and 326 of the first subpixel PX1, the second subpixel PX2 and the third subpixel PX3, respectively, may be provided to assemble the first semiconductor light-emitting element 150-1, the second semiconductor light-emitting element 150-2 and the third semiconductor light-emitting element 150-3, respectively.

The first assembling wirings 321, 323 and 325 and the second assembling wirings 322, 324 and 326 may have a structure that is symmetrical with respect to a reference line in the second direction Y that passes through the center of the first assembly hole 340H1, the second assembly hole 340H2 and the third assembly hole 340H3, respectively.

In each of the first subpixel PX1, the second subpixel PX2 and the third subpixel PX3, the first assembling wirings 321, 323 and 325 may comprise first conductive electrodes 321-1, 323-1 and 325-1 and second conductive electrodes 321-2, 323-2 and 325-2, and the second assembling wirings 322, 324 and 326 may comprise first conductive electrodes 322-1, 324-1 and 326-1 and second conductive electrodes 322-2, 324-2 and 326-2.

The first conductive electrodes 321-1, 323-1 and 325-1 of the first assembling wirings 321, 323 and 325 may be disposed lengthwise along the second direction Y. Parts of the first conductive electrodes 321-1, 323-1 and 325-1 of the first assembling wirings 321, 323 and 325 may comprise protruding electrodes extending toward the first assembly hole 340H1, the second assembly hole 340H2 and the third assembly hole 340H3, respectively. The protruding electrodes of the first conductive electrodes 321-1, 323-1 and 325-1 of the first assembling wirings 321, 323 and 325 may vertically overlap with the first assembly hole 340H1, the second assembly hole 340H2 and the third assembly hole 340H3, respectively.

The second conductive electrodes 321-2, 323-2 and 325-2 of the first assembling wirings 321, 323 and 325 may be connected to the first conductive electrodes 321-1, 323-1 and 325-1. respectively, and may be vertically overlapped with the first semiconductor light-emitting element 150-1, the second semiconductor light-emitting element 150-2 and the third semiconductor light-emitting element 150-3, respectively. Parts of the second conductive electrodes 321-2, 323-2 and 325-2 of the first assembling wirings 321, 323 and 325 may be vertically overlapped with the protruding electrodes of the first conductive electrodes 321-1. 323-1 and 325-1, respectively. For example, the second conductive electrodes 321-2, 323-2 and 325-2 may be in contact with the side and upper surfaces of the protruding electrodes of the first conductive electrodes 321-1, 323-1 and 325-1, respectively, but is not limited thereto. That is, the second conductive electrodes 321-2, 323-2 and 325-2 may also be in contact with the lower surfaces of the protruding electrodes, respectively.

The first conductive electrodes 322-1, 324-1 and 326-1 of the second assembling wirings 322, 324 and 326 may be disposed lengthwise along the second direction Y. Parts of the first conductive electrodes 322-1, 324-1 and 326-1 of the second assembling wirings 322, 324 and 326 may comprise protruding electrodes extending toward the first assembly hole 340H1, the second assembly hole 340H2 and the third assembly hole 340H3, respectively. The protruding electrodes of the first conductive electrodes 322-1, 324-1 and 326-1 of the second assembling wirings 322, 324 and 326 may vertically overlap with the first assembly hole 340H1, the second assembly hole 340H2 and the third assembly hole 340H3, respectively.

The second conductive electrodes 322-2, 324-2 and 326-2 of the second assembling wirings 322, 324 and 326 may be connected to the first conductive electrodes 322-1, 324-1 and 326-1, respectively, and may be vertically overlapped with the first semiconductor light-emitting element 150-1, the second semiconductor light-emitting element 150-2 and the third semiconductor light-emitting element 150-3, respectively. Parts of the second conductive electrodes 322-2, 324-2 and 326-2 of the second assembling wirings 322, 324 and 326 may be vertically overlapped with the protruding electrodes of the first conductive electrodes 322-1, 324-1 and 326-1, respectively. For example, the second conductive electrodes 322-2, 324-2 and 326-2 may be in contact with the side and upper surfaces of the protruding electrodes of the first conductive electrodes 322-1, 324-1 and 326-1, respectively, but is not limited thereto. That is, the second conductive electrodes 322-2, 324-2 and 326-2 may also be in contact with the lower surfaces of the protruding electrodes, respectively.

For example, the first conductive electrodes 321-1, 323-1 and 325-1 of the first assembling wirings 321, 323 and 325 and the first conductive electrodes 322-1, 324-1 and 326-1 of the second assembling wirings 322, 324 and 326 may have a structure symmetrical with respect to a reference line in the second direction Y passing through the center of each of the first assembly hole 340H1, the second assembly hole 340H2 and the third assembly hole 340H3, respectively. For example, the second conductive electrodes 321-2, 323-2, and 325-2 of the first assembling wirings 321, 323, and 325, and the second conductive electrodes 322-2, 324-2, and 326-2 of the second assembling wirings 322, 324, and 326 may have a structure symmetrical with respect to a reference line in the second direction Y passing through the center of each of the first assembly hole 340H1, the second assembly hole 340H2, and the third assembly hole 340H3, respectively.

Meanwhile, the plurality of subpixels PX1, PX2, and PX3 may comprise the plurality of connection electrodes 370-1, 370-2, and 370-3, respectively.

The first connection electrode 370-1 may be disposed around the first semiconductor light-emitting element 150-1 within the first assembly hole 340H1 of the first sub-pixel PX1. One side of the first connection electrode 370-1 may be connected to a side portion of the first semiconductor light-emitting element 150-1. One side of the first connection electrode 370-1 may be connected to the side electrode 155 of the first semiconductor light-emitting element 150-1. The other side of the first connection electrode 370-1 may be connected to the first assembling wiring 321 and/or the second assembling wiring 322. The other side of the first connection electrode 370-1 may be in contact with the first conductive electrode 321-1 of the first assembling wiring 321. The other side of the first connection electrode 370-1 may be in contact with the second conductive electrode 321-2 of the first assembling wiring 321. The other side of the first connection electrode 370-1 may be in contact with the first conductive electrode 322-1 of the second assembling wiring 322. The other side of the first connection electrode 370-1 may be in contact with the second conductive electrode 322-2 of the second assembling wiring 322.

A part of the second conductive electrode 321-2 of the first assembling wiring 321 may vertically overlap with the other side of the first connection electrode 370-1, and another part of the second conductive electrode 321-2 of the first assembling wiring 321 may vertically overlap with the first semiconductor light-emitting element 150-1. A part of the second conductive electrode 322-2 of the second assembling wiring 322 may vertically overlap with the other side of the first connection electrode 370-1, and another part of the second conductive electrode 322-2 of the second assembling wiring 322 may vertically overlap with the first semiconductor light-emitting element 150-1.

The second connection electrode 370-2 may be disposed around the second semiconductor light-emitting element 150-2 within the second assembly hole 340H2 of the second subpixel PX2. One side of the second connection electrode 370-2 may be connected to a side portion of the second semiconductor light-emitting element 150-2. One side of the second connection electrode 370-2 may be connected to the side electrode of the second semiconductor light-emitting element 150-2. The other side of the second connection electrode 370-2 may be connected to the first assembling wiring 323 and/or the second assembling wiring 324. The other side of the second connection electrode 370-2 may be in contact with the first conductive electrode 323-1 of the first assembling wiring 323. The other side of the second connection electrode 370-2 may be in contact with the second conductive electrode 323-2 of the first assembling wiring 323. The other side of the second connection electrode 370-2 may be in contact with the first conductive electrode 324-1 of the second assembling wiring 324. The other side of the second connection electrode 370-2 may be in contact with the second conductive electrode 324-2 of the second assembling wiring 324.

A part of the second conductive electrode 323-2 of the first assembling wiring 323 may vertically overlap with the other side of the second connection electrode 370-2, and another part of the second conductive electrode 323-2 of the first assembling wiring 323 may vertically overlap with the second semiconductor light-emitting element 150-2. A part of the second conductive electrode 324-2 of the second assembling wiring 324 may vertically overlap with the other side of the second connection electrode 370-2, and another part of the second conductive electrode 324-2 of the second assembling wiring 324 may vertically overlap with the second semiconductor light-emitting element 150-2.

The third connecting electrode 370-3 may be disposed around the third semiconductor light-emitting element 150-3 within the third assembly hole 340H3 of the third sub-pixel PX3. One side of the third connecting electrode 370-3 may be connected to a side portion of the third semiconductor light-emitting element 150-3. One side of the third connecting electrode 370-3 may be connected to the side electrode of the third semiconductor light-emitting element 150-3. The other side of the third connection electrode 370-3 may be connected to the first assembling wiring 325 and/or the second assembling wiring 326. The other side of the third connection electrode 370-3 may be in contact with the first conductive electrode 325-1 of the first assembling wiring 325. The other side of the third connection electrode 370-3 may be in contact with the second conductive electrode 326-1 of the first assembling wiring 325. The other side of the third connection electrode 370-3 may be in contact with the first conductive electrode 326-1 of the second assembling wiring 326. The other side of the third connection electrode 370-3 may be in contact with the second conductive electrode 326-2 of the second assembling wiring 326.

A part of the second conductive electrode 325-2 of the first assembling wiring 325 may vertically overlap with the other side of the third connection electrode 370-3, and another part of the second conductive electrode 325-2 of the first assembling wiring 325 may vertically overlap with the third semiconductor light-emitting element 150-3. A part of the second conductive electrode 326-2 of the second assembling wiring 326 may vertically overlap with the other side of the third connection electrode 370-3, and another part of the second conductive electrode 326-2 of the second assembling wiring 326 may vertically overlap with the third semiconductor light-emitting element 150-3.

Meanwhile, the first connection electrode 370-1 may be attached to the first semiconductor light-emitting element 150-1, the first conductive electrode 321-1 and the second conductive electrode 321-2 of the first assembling wiring 321, the first conductive electrode 322-1 and the second conductive electrode 322-2 of the second assembling wiring 322, as well as the first insulating layer 330 and the partition wall 340 exposed within the first assembly hole 340H1. Accordingly, the fixing force of the first assembling wiring 321, the second assembling wiring 322, and the first semiconductor light-emitting element 150-1 can be strengthened by the first connection electrode 370-1.

The second connection electrode 370-2 may be attached to the second semiconductor light-emitting element 150-2, the first conductive electrode 323-1 and the second conductive electrode 323-2 of the first assembling wiring 323 and the first conductive electrode 324-1 and the second conductive electrode 324-2 of the second assembling wiring 324, as well as the first insulating layer 330 and the partition wall 340 exposed within the second assembly hole 340H2. Accordingly, the fixing force of the first assembling wiring 323, the second assembling wiring 324, and the second semiconductor light-emitting element 150-2 can be strengthened by the second connection electrode 370-2.

The third connection electrode 370-3 may be attached to the third semiconductor light-emitting element 150-3, the first conductive electrode 325-1 and the second conductive electrode 325-2 of the first assembling wiring 325 and the first conductive electrode 326-1 and the second conductive electrode 326-2 of the second assembling wiring 326, as well as the first insulating layer 330 and the partition wall 340 exposed within the third assembly hole 340H3. Accordingly, the fixing force of the first assembling wiring 325, the second assembling wiring 326, and the third semiconductor light-emitting element 150-3 can be strengthened by the third connection electrode 370-3.

Meanwhile, the electrode wiring 360 may be disposed on a plurality of pixels PX. That is, the electrode wiring 360 may be disposed on the first subpixel PX1, the second subpixel PX2, and the third subpixel PX3 constituting each of the plurality of pixels PX. For example, the electrode wiring 360 may be disposed on the first semiconductor light-emitting element 150-1 of the first subpixel PX1, the second semiconductor light-emitting element 150-2 of the second subpixel PX2, and the third semiconductor light-emitting element 150-3 of the third subpixel PX3. For example, the electrode wiring 360 may be disposed on the partition wall 340. For example, the electrode wiring 360 may be disposed on the second insulating layer 350 of each of the first assembly hole 340H1, the second assembly hole 340H2, and the third assembly hole 340H3 of the first subpixel PX1, the second subpixel PX2, and the third subpixel PX3, respectively.

The electrode wiring 360 may be commonly connected to the first semiconductor light-emitting element 150-1, the second semiconductor light-emitting element 150-2, and the third semiconductor light-emitting element 150-3.

The electrode wiring 360 may be in contact with an upper surface 151a of the first semiconductor light-emitting element 150-1. The electrode wiring 360 may be in contact with the upper surface 151a of the first conductivity type semiconductor layer 151 of the first semiconductor light-emitting element 150-1. When the upper electrode is disposed on the first conductivity type semiconductor layer 151, the electrode wiring 360 may be in contact with the upper surface of the upper electrode. The upper electrode may comprise an ohmic layer for ohmic formation.

The electrode wiring 360 may be in contact with an upper surface of the second semiconductor light-emitting element 150-2. The electrode wiring 360 may be in contact with the upper surface of the first conductivity type semiconductor layer 151 of the second semiconductor light-emitting element 150-2. When the upper electrode is disposed on the first conductivity type semiconductor layer 151, the electrode wiring 360 may be in contact with the upper surface of the upper electrode. The upper electrode may comprise an ohmic layer for ohmic formation.

The electrode wiring 360 may be in contact with an upper surface of the third semiconductor light-emitting element 150-3. The electrode wiring 360 may be in contact with the upper surface of the first conductivity type semiconductor layer 151 of the third semiconductor light-emitting element 150-3. When the upper electrode is disposed on the first conductivity type semiconductor layer 151, the electrode wiring 360 may be in contact with the upper surface of the upper electrode. The upper electrode may comprise an ohmic layer for ohmic formation.

The electrode wiring 360 may be in contact with an upper surface of the partition wall 340. The upper surface 151a of each of the first semiconductor light-emitting element 150-1, the second semiconductor light-emitting element 150-2, and the third semiconductor light-emitting element 150-3 may be positioned on the same horizontal line as the upper surface of the partition wall 340, but is not limited thereto. When the upper surface of the partition wall 340 is positioned lower than the upper surface 151a of each of the first semiconductor light-emitting element 150-1, the second semiconductor light-emitting element 150-2, and the third semiconductor light-emitting element 150-3, the upper surface 151a of each of the first semiconductor light-emitting element 150-1, the second semiconductor light-emitting element 150-2, and the third semiconductor light-emitting element 150-3 and the upper surface of the partition wall 340 are not positioned on the same horizontal line.

Meanwhile, the first assembling wirings 321, 323 and 325 and/or the second assembling wirings 322, 324 and 326 may be anode electrodes, and the electrode wiring 360 may be a cathode electrode. In this instance, a negative (−) voltage may be supplied to the electrode wiring 360, and a positive (+) voltage may be supplied to the first assembling wirings 321, 323 and 325 and/or the second assembling wirings 322, 324 and 326, so that current may flow in the following order: first assembling wirings 321, 323 and 325 and/or second assembling wirings 322, 324 and 326→first semiconductor light-emitting element 150-1, second semiconductor light-emitting element 150-2 or third semiconductor light-emitting element 150-3→electrode wiring 360. For example, a first current may flow from a lower part to an upper part of the first semiconductor light-emitting element 150-1, and red light having a luminance corresponding to the first current may be emitted from the first semiconductor light-emitting element 150-1. For example, a second current may flow from a lower part to an upper part of the second semiconductor light-emitting element 150-2, and green light having a luminance corresponding to the second current may be emitted from the second semiconductor light-emitting element 150-2. For example, a third current may flow from a lower part to an upper part of the third semiconductor light-emitting element 150-3, and blue light having a luminance corresponding to the third current may be emitted from the third semiconductor light-emitting element 150-3. Here, the first current, the second current, and the third current may each be a driving current for generating light.

Referring again to FIGS. 11 to 13, the display device 300 according to the embodiment may comprise a first insulating layer 330 and a second insulating layer 350.

The first insulating layer 330 may be disposed on the first assembling wirings 321, 323, and 325 and the second assembling wirings 322, 324, and 326. The first insulating layer 330 can prevent the first assembling wirings 321, 323, and 325 and the second assembling wirings 322, 324, and 326 from being exposed to a fluid and corroded during self-assembly. The first insulating layer 330 can prevent an electrical short between the first assembling wirings 321, 323, and 325 and the second assembling wirings 322, 324, and 326. The first insulating layer 330 can help to more easily assemble the plurality of semiconductor light-emitting elements 150-1, 150-2, and 150-3. To this end, the first insulating layer 330 may be made of an insulating material having a permittivity: The DEP force may vary in intensity depending on the dielectric constant of the first insulating layer 330 as well as the dielectric constant within the plurality of semiconductor light-emitting elements 150-1, 150-2, and 150-3, such as the dielectric constant of the passivation layer 157.

The first insulating layer 330 may be formed of a material having excellent insulating properties. For example, the first insulating layer 330 may be formed of an inorganic insulating material such as SiNx or SiOx, but is not limited thereto.

The second insulating layer 350 may be disposed in the plurality of subpixels PX1, PX2, and PX3. That is, the second insulating layer 350 may be disposed in each of the first assembly hole 340H1 of the first subpixel PX1, the second assembly hole 340H2 of the second subpixel PX2, and the third assembly hole 340H3 of the third subpixel PX3. The second insulating layer 350 may be disposed around the first semiconductor light-emitting element 150-1 in the first assembly hole 340H1. The second insulating layer 350 may be disposed on the first connection electrode 370-1 in the first assembly hole 340H1. The second insulating layer 350 may be disposed around the second semiconductor light-emitting element 150-2 in the second assembly hole 340H2. The second insulating layer 350 may be disposed on the second connection electrode 370-2 in the second assembly hole 340H2. The second insulating layer 350 may be disposed around the third semiconductor light-emitting element 150-3 in the third assembly hole 340H3. The second insulating layer 350 may be disposed on the third connection electrode 370-3 in the third assembly hole 340H3.

An upper surface of the second insulating layer 350 may be positioned on the same horizontal line as ab upper surface of the partition wall 340. The upper surface of the second insulating layer 350 may be positioned on the same horizontal line as the upper surface 151a of each of the first semiconductor light-emitting element 150-1, the second semiconductor light-emitting element 150-2, and the third semiconductor light-emitting element 150-3.

Meanwhile, as illustrated in FIG. 12, the first signal line SL1, the second signal line SL2, and the third signal line SL3 may be electrically connected to the first assembling wirings 321, 323, and 325 and the second assembling wirings 322, 324, and 326 of the first subpixel PX1, the second subpixel PX2, and the third subpixel PX3, respectively, through the contact holes CTH1a, CTH1b, CTH2a, CTH2b, CTH3a, and CTH3b. Although the drawing illustrates that each of the first signal line SL1, the second signal line SL2, and the third signal line SL3 is connected to all of the first assembling wirings 321, 323, and 325, and the second assembling wirings 322, 324, and 326, they may be selectively connected to either the first assembling wirings 321, 323, and 325, or the second assembling wirings 322, 324, and 326.

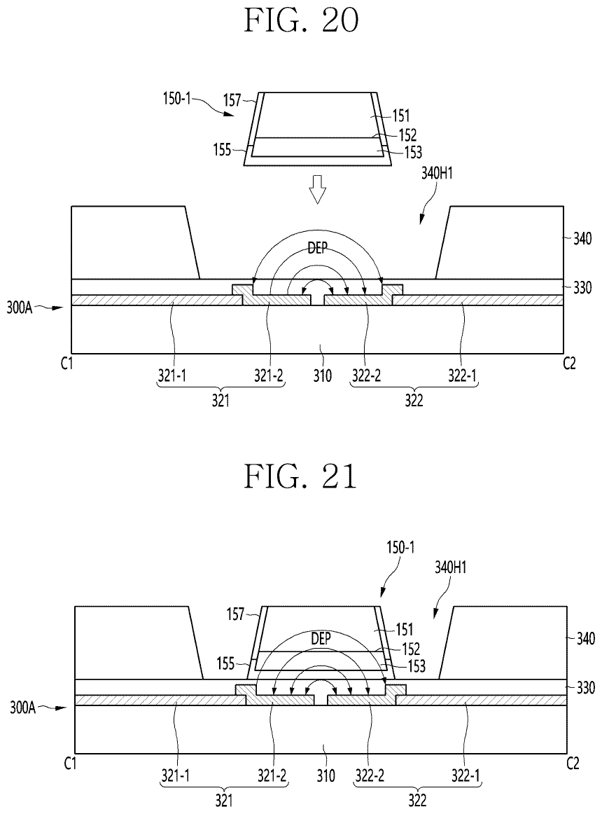

Meanwhile, FIG. 15 illustrates an image displayed according to a bottom emission method in a display device according to an embodiment.

As illustrated in FIG. 15, light generated from the first semiconductor light-emitting element 150-1 may be directly emitted in a downward direction or may be reflected by the electrode wiring 360 and then travel in a downward direction. The red light traveling in a downward direction may transmit through the first assembling wiring 321 and/or the second assembling wiring 322. To this end, the electrode wiring 360 may be a reflective electrode, and the first assembling wiring 321 and/or the second assembling wiring 322 may be transparent electrodes. The first conductive electrode 321-1 of the first assembling wiring 321 and/or the first conductive electrode 322-1 of the second assembling wiring 322 may be metal electrodes, and the second conductive electrode 321-2 of the first assembling wiring 321 and/or the second conductive electrode 322-2 of the second assembling wiring 322 may be transparent electrodes. Even if the first conductive electrode 321-1 of the first assembling wiring 321 and/or the first conductive electrode 322-1 of the second assembling wiring 322 are opaque metal electrodes, by designing them to have a thickness that allows red light wavelengths to be transmitted, red light may be transmitted through the first conductive electrode 321-1 of the first assembling wiring 321 and/or the first conductive electrode 322-1 of the second assembling wiring 322.

Although not illustrated, the green light of the second semiconductor light-emitting element 150-2 and the blue light of the third semiconductor light-emitting element 150-3 may also be emitted in a bottom-emission manner that proceeds in a downward direction.

According to an embodiment, the electrode wiring 360 can improve the luminance of light by reflecting light as a reflective electrode.

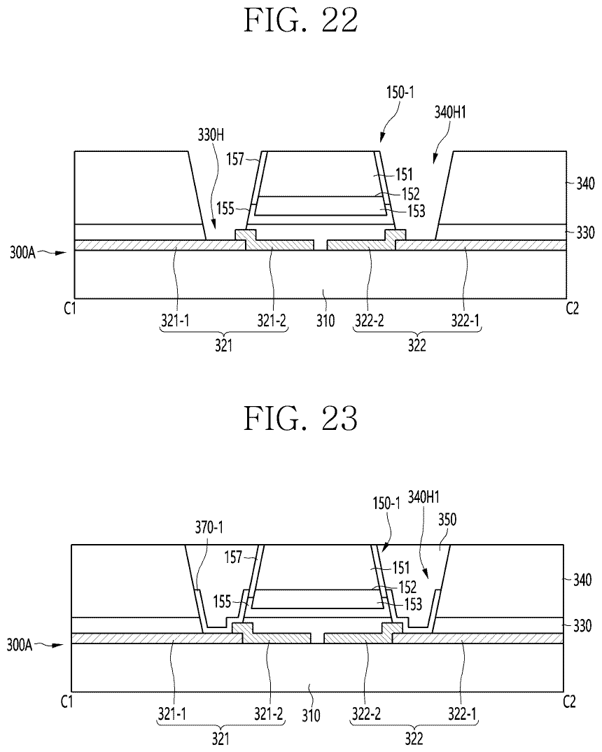

FIG. 16 illustrates an image displayed according to a top emission method in a display device according to an embodiment.

As illustrated in FIG. 16, light generated from the first semiconductor light-emitting element 150-1 may be directly emitted in an upward direction or may be reflected by the first assembling wiring 321 and/or the second assembling wiring 322 and then may proceed in an upward direction. Red light proceeding in an upward direction may transmit through the electrode wiring 360. To this end, the electrode wiring 360 may be a transparent electrode, and the first assembling wiring 321 and/or the second assembling wiring 322 may be reflective electrodes. The second conductive electrode 321-2 of the first assembling wiring 321 and/or the second conductive electrode 322-2 of the second assembling wiring 322 may be reflective electrodes.

Although not illustrated, the green light of the second semiconductor light-emitting element 150-2 and the blue light of the third semiconductor light-emitting element 150-3 may also be emitted in a top-emission manner that proceeds in an upward direction.

According to an embodiment, the electrode wiring 360 may be directly connected to the upper side of each of the first semiconductor light-emitting element 150-1, the second semiconductor light-emitting element 150-2, and the third semiconductor light-emitting element 150-3 without penetrating a separate insulating layer. Therefore, in the embodiment, when the electrode wiring is formed on a separate insulating layer and a contact hole is formed to individually connect to each semiconductor light-emitting element, an electrical short between the electrode wiring and the connection electrode around each semiconductor light-emitting element due to a shift of the contact hole caused by misalignment of the pattern mask can be prevented.

According to an embodiment, by disposing a single electrode wiring 360 in the shape of a plate on the first semiconductor light-emitting element 150-1, the second semiconductor light-emitting element 150-2, and the third semiconductor light-emitting element 150-3, without the need to individually form the first electrode wiring, the second electrode wiring, and the third electrode wiring for connecting to the first semiconductor light-emitting element 150-1, the second semiconductor light-emitting element 150-2, and the third semiconductor light-emitting element 150-3 on separate insulating layers, the structure is simple and the process is easy.

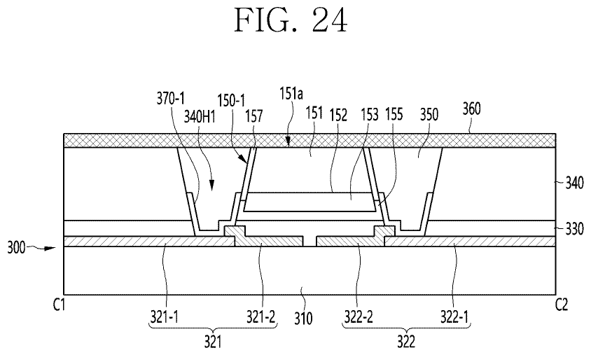

FIGS. 17 to 24 are cross-sectional views illustrating a manufacturing process of a display device according to an embodiment.

FIGS. 17 to 24 illustrate a manufacturing process of the first subpixel PX of the display device 300, but the second subpixel PX2 and the third subpixel PX3 may also be the same as the manufacturing process of the first subpixel PX1 described below.

As illustrated in FIG. 17, the first conductive electrodes 321-1 and 322-1 may be formed spaced apart from each other on the substrate 310. That is, the first conductive electrodes 321-1 and 322-1 may be formed by depositing and patterning a conductive film on the substrate 310. The first conductive electrodes 321-1 and 322-1 may be opaque electrodes, transparent electrodes, or reflective electrodes. The first conductive electrodes 321-1 and 322-1 may be a single layer or a multilayer.

As illustrated in FIG. 18, the second conductive electrodes 321-2 and 322-2 may be formed spaced apart from each other on the substrate 310. That is, the second conductive electrodes 321-2 and 322-2 may be formed by depositing and patterning a conductive film on the substrate 310. The second conductive electrodes 321-2 and 322-2 may be opaque electrodes, transparent electrodes, or reflective electrodes. The second conductive electrodes 321-2 and 322-2 may be single-layer or multi-layer.

Parts of the second conductive electrodes 321-2 and 322-2 may vertically overlap parts of the first conductive electrodes 321-1 and 322-1, thereby being electrically connected to each other.

The first assembling wiring 321 may be formed by the first conductive electrode 321-1 and the second conductive electrode 321-2 connected to the first conductive electrode 321-1. The second assembling wiring 322 may be formed by the first conductive electrode 322-1 and the second conductive electrode 322-2 connected to the first conductive electrode 322-1.

The first assembling wiring 321 and the second assembling wiring 322 may be used to assemble the first semiconductor light-emitting element 150-1 later.

As illustrated in FIG. 19, a first insulating layer 330 may be formed on the first assembling wiring 321 and the second assembling wiring 322. The first insulating layer 330 may be formed on the entire region of the substrate 310, but is not limited thereto. The first insulating layer 330 may be formed of an inorganic material having excellent insulating properties, but is not limited thereto. The first insulating layer 330 may be formed of an insulating material having a dielectric constant.

As illustrated in FIG. 20, a partition wall 340 may be formed on the first insulating layer 330. The partition wall 340 may have a first assembly hole 340H1. After the partition wall 340 is formed on the first insulating layer 330, the partition wall 340 may be formed on the first assembling wiring 321 and the second assembling wiring 322 by removing the partition wall 340. That is, the upper surface of the first insulating layer 330 may be exposed by removing the partition wall 340.

The partition wall 340 may be formed to have a thickness equal to or smaller than the thickness of the first semiconductor light-emitting element 150-1 to be assembled into the first assembly hole 340H1 later.

For example, the first assembly hole 340H1 may be formed on the second conductive electrode 321-2 of the first assembling wiring 321 and the second conductive electrode 322-2 of the second assembling wiring 322, but is not limited thereto.

In this way, the substrate 310 on which the first assembling wiring 321, the second assembling wiring 322, and the first assembly hole 340H1 are formed may be called an assembly substrate 300A or a backplane substrate. The assembly substrate 300A may be provided with driving circuits for driving each of the first semiconductor light-emitting element 150-1 of the first subpixel PX1, the second semiconductor light-emitting element 150-2 of the second subpixel PX2, and the third semiconductor light-emitting element 150-3 of the third subpixel PX3, such as the scan transistor ST, the driving transistor DT, and the capacitor Cst illustrated in FIG. 7.

Meanwhile, a self-assembly process may be performed using the assembly substrate 300A manufactured in this manner.

First, after the fluid 1200 is filled in the chamber (1300 of FIG. 10), the assembly substrate 300A may be fastened to the chamber 1300. Thereafter, a plurality of first semiconductor light-emitting elements 150-1 may be inserted into the fluid 1200. By applying an AC voltage to the first assembling wiring 321 and the second assembling wiring 322, a DEP force may be formed in the first assembly hole 340H1. Thereafter, at least one or more assembly device 1100 may rotate and/or move at the rear of the assembly substrate 300A, so that the plurality of first semiconductor light-emitting elements 150-1 may rotate and/or move.

Among the plurality of first semiconductor light-emitting elements 150-1 rotating and/or moving within the chamber 1300, the first semiconductor light-emitting element 150-1 closest to the first assembly hole 340H1 may be assembled into the first assembly hole 340H1 by the DEP force formed by the AC voltage between the first assembling wiring 321 and the second assembling wiring 322. A lower side of the first semiconductor light-emitting element 150-1 assembled in the first assembly hole 340H1 may be in contact with an upper surface of the first insulating layer 330 or may be positioned on the upper surface of the first insulating layer 330.

As illustrated in FIG. 21, the first semiconductor light-emitting element 150-1 assembled in the first assembly hole 340H1 may be fixed by the DEP force and does not fall out of the first assembly hole 340H1.

As illustrated in FIG. 22, the first insulating layer 330 positioned around the first semiconductor light-emitting element 150-1 in the first assembly hole 340H1 may be removed, so that a connection hole 330H in which the upper surface of the first assembling wiring 321 and/or the second assembling wiring 322 is exposed may be formed. The upper surface of a part of the first conductive electrode 321-1 and 322-1 of the first assembling wiring 321 and/or the second assembling wiring 322 may be exposed by the connection hole 330H. The upper surface of a part of the second conductive electrode 321-2 and 322-2 of the first assembling wiring 321 and/or the second assembling wiring 322 may be exposed by the connection hole 330H. The connection hole 330H may be used to electrically connect the first semiconductor light-emitting element 150-1 and the first assembling wiring 321 and/or the second assembling wiring 322.

That is, as illustrated in FIG. 23, a first connection electrode 370-1 may be formed around the first semiconductor light-emitting element 150-1 in the first assembly hole 340H1. The first connection electrode 370-1 may be in contact with the side electrode 155 of the first semiconductor light-emitting element 150-1. The first connection electrode 370-1 may be in contact with a part of the passivation layer 157 of the first semiconductor light-emitting element 150-1. The first connection electrode 370-1 may be in contact with a part of the first conductive electrodes 321-1 and 322-1 of the first assembling wiring 321 and/or the second assembling wiring 322. The first connection electrode 370-1 may contact a part of the second conductive electrodes 321-2 and 322-2 of the first assembling wiring 321 and/or the second assembling wiring 322. The first connection electrode 370-1 may contact the first insulating layer 330 and the partition wall 340 in the first assembly hole 340H1.

Meanwhile, the second insulating layer 350 may be formed around the first semiconductor light-emitting element 150-1 in the first assembly hole 340H1. Since the second insulating layer 350 is formed with a thick thickness, it may be formed of an organic material that is easy to form a thickness, but is not limited thereto.

The second insulating layer 350 may be disposed on the first connection electrode 370-1 in the first assembly hole 340H1. The upper surface of the second insulating layer 350 may be positioned on the same horizontal line as the upper surface of the partition wall 340. The upper surface of the second insulating layer 350 may be positioned on the same horizontal line as the upper surface 151a of the first semiconductor light-emitting element 150-1. The fixing force of each of the first connection electrode 370-1 and the first semiconductor light-emitting element 150-1 can be strengthened by the second insulating layer 350.

As illustrated in FIG. 24, the electrode wiring 360 may be formed on the substrate 310. A conductive film may be deposited and patterned on the substrate 310, so that the electrode wiring 360 may be formed. That is, in forming the electrode wiring 360, only a deposition process may be required and no contact hole formation process is required, so that the process is easy and the process time can be shortened.

The electrode wiring 360 may be formed on the first semiconductor light-emitting element 150-1. The electrode wiring 360 may be formed on the partition wall 340. The electrode wiring 360 may be formed on the second insulating layer 350.

Although not illustrated, the electrode wiring 360 may be formed not only on the first subpixel PX1 comprising the first semiconductor light-emitting element 150-1, but also on the second subpixel PX2 comprising the second semiconductor light-emitting element 150-2 and the third subpixel PX3 comprising the third semiconductor light-emitting element 150-3.

Since the electrode wiring 360 is integrally formed on the first subpixel PX1, the second subpixel PX2 and the third subpixel PX3 by the same process, the structure is simple and the process is easy.

By forming the electrode wiring 360 by the post-process, the display device 300 may be manufactured.

Meanwhile, the display device 300 regarding the unit pixel PX comprising the first subpixel PX1, the second subpixel PX2 and the third subpixel PX3 has been described above.

However, in order to implement an image in the display device 300, a display panel comprising a plurality of pixels PX and various circuit devices for driving the display panel are required.

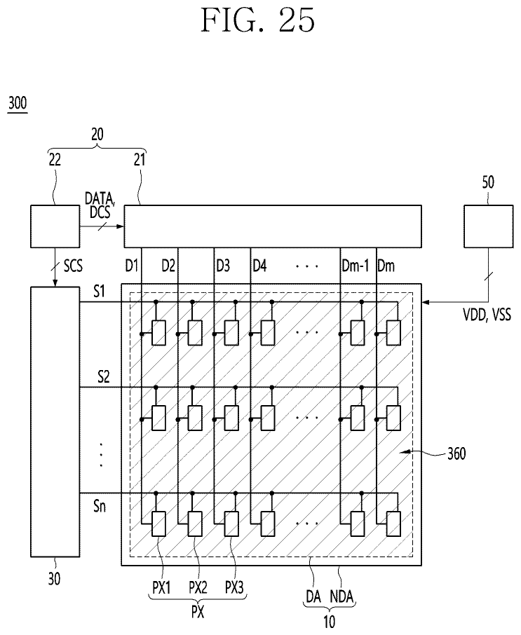

FIG. 25 is a block diagram illustrating a display device according to an embodiment.

Referring to FIG. 25, the display device 300 according to the embodiment may comprise a display panel 10, a driving circuit 20, a scan driving unit 30, and a power supply circuit 50.

Since the driving circuit 20, the scan driving unit 30, and the power supply circuit 50 are described in FIG. 6, further descriptions thereof will be omitted.

The display panel 10 may be divided into a display region DA and a non-display region NDA disposed around the display region DA. The display region DA is a region where pixels PX are formed to display an image.

The structure of each pixel PX is illustrated in FIGS. 11 to 13.

In the embodiment, the electrode wiring 360 may be integrally disposed on the display region DA of the display panel 10.

That is, since the electrode wiring 360 is integrally disposed not only on the pixels PX of the display region DA but also on the boundary region between the pixels PX, the structure is simple and the process is easy.

Referring to FIGS. 11 to 13 and FIG. 25, the electrode wiring 360 may be disposed on the first semiconductor light-emitting element 150-1, the second semiconductor light-emitting element 150-2, the third semiconductor light-emitting element 150-3, the partition wall 340, and the second insulating layer 350 of each of the pixels PX of the display region DA. The upper surface and/or the lower surface of the electrode wiring 360 may have a horizontal surface.

Meanwhile, the display device described above may be a display panel. That is, in the embodiment, the display device and the display panel may be understood to have the same meaning. In the embodiment, the display device in the practical sense may comprise a display panel and a controller (or processor) capable of controlling the display panel to display an image.

The above detailed description should not be construed as limiting in all respects and should be considered illustrative. The scope of the embodiment should be determined by reasonable interpretation of the appended claims, and all changes within the equivalent range of the embodiment are included in the scope of the embodiment.

### Industrial Applicability

The embodiment can be adopted in the display field for displaying images or information. The embodiment can be adopted in the display field for displaying images or information using a semiconductor light-emitting element. The semiconductor light-emitting element can be a micro-level semiconductor light-emitting element or a nano-level semiconductor light-emitting element.

For example, the embodiment may be adopted in a TV, signage, a smart phone, a mobile phone, a mobile terminal, a HUD for an automobile, a backlight unit for a laptop computer, and a display device for VR or AR.

1. A display device, comprising:
a substrate;
a first assembling wiring on the substrate;
a second assembling wiring on the substrate;
a partition wall comprising an assembly hole on the first assembling wiring and the second assembling wiring;
a semiconductor light-emitting element in the assembly hole;
a connection electrode on a side portion of the semiconductor light-emitting element; and
an electrode wiring on an upper side of the semiconductor light-emitting element,
wherein each of the first assembling wiring and the second assembling wiring comprises:
a first conductive electrode configured to vertically overlap the assembly hole; and
a second conductive electrode configured to be connected to the first conductive electrode and vertically overlap the semiconductor light-emitting element.

2. The display device of claim 1, wherein the substrate comprises a first subpixel, a second subpixel, and a third subpixel,
wherein the semiconductor light-emitting element comprises:
at least one first semiconductor light-emitting element in the first subpixel;
at least one second semiconductor light-emitting element in the second subpixel; and
at least one third semiconductor light-emitting element in the third subpixel, and
wherein each of the first semiconductor light-emitting element, the second semiconductor light-emitting element, and the third semiconductor light-emitting element is configured to emit different light.

3. The display device of claim 2, wherein the electrode wiring is configured to be commonly connected to the first semiconductor light-emitting element, the second semiconductor light-emitting element, and the third semiconductor light-emitting element.

4. The display device of claim 2, wherein the connection electrode comprises:
a first connection electrode around the first semiconductor light-emitting element of the first subpixel:
a second connection electrode around the second semiconductor light-emitting element of the second subpixel; and
a third connection electrode around the third semiconductor light-emitting element of the third subpixel.

5. The display device of claim 4, wherein each of the first semiconductor light-emitting element, the second semiconductor light-emitting element, and the third semiconductor light-emitting element comprises:
a light-emitting layer: and
a side electrode configured to extend from a lower side of the light-emitting layer and disposed on a side portion of the light-emitting layer,
wherein each of the first connection electrode, the second connection electrode, and the third connection electrode is in contact with the side electrode.

6. The display device of claim 4, wherein each of the first connection electrode, the second connection electrode, and the third connection electrode is configured to be connected to at least one of the first assembling wiring or the second assembling wiring.

7. The display device of claim 6, wherein each of the first connection electrode, the second connection electrode, and the third connection electrode is in contact with the first conductive electrode.

8. The display device of claim 7, wherein each of the first connection electrode, the second connection electrode, and the third connection electrode is in contact with the second conductive electrode.

9. The display device of claim 2, wherein the electrode wiring is disposed on the first semiconductor light-emitting element, the second semiconductor light-emitting element, the third semiconductor light-emitting element, and the partition wall.

10. The display device of claim 2, wherein the electrode wiring is disposed on an upper surface of each of the first semiconductor light-emitting element, the second semiconductor light-emitting element, and the third semiconductor light-emitting element.

11. The display device of claim 10, wherein the upper surface of each of the first semiconductor light-emitting element, the second semiconductor light-emitting element, and the third semiconductor light-emitting element is positioned on a same horizontal line as an upper surface of the partition wall.

12. The display device of claim 1, wherein at least one of the first assembling wiring or the second assembling wiring is an anode electrode, and the electrode wiring is a cathode electrode.

13. The display device of claim 1, wherein the first conductive electrode is a metal electrode.

14. The display device of claim 1, wherein the second conductive electrode is a transparent electrode, and the electrode wiring is a reflective electrode.

15. The display device of claim 1, wherein the second conductive electrode is a reflective electrode, and the electrode wiring is a transparent electrode.

16. The display device of claim 1, wherein the semiconductor light-emitting element has an inclined surface so that a size of the lower side thereof is greater than a size of an upper side thereof.
